(19) United States
(12) Patent Application Publication
(10) Pub. No.: US 2013/0071565 A1
(43) Pub. Date: Mar. 21, 2013

(54) Apparatuses and Methods for Large-Scale Production of Hybrid Fibers Containing Carbon Nanostructures and Related Materials

(71) Applicants: Harry C. Malecki, Abingdon, MD (US); Jason L. Dahne, Hunt Valley, MD (US); James P. Loebach, Bel Air, MD (US); Randy L. Gaigler, Parkville, MD (US); Jordan T. Ledford, Baltimore, MD (US)

(72) Inventors: Harry C. Malecki, Abingdon, MD (US); Jason L. Dahne, Hunt Valley, MD (US); James P. Loebach, Bel Air, MD (US); Randy L. Gaigler, Parkville, MD (US); Jordan T. Ledford, Baltimore, MD (US)

(73) Assignee: Applied Nanostructured Solutions, LLC, Baltimore, MD (US)

(21) Appl. No.: 13/244,140

(22) Filed: Sep. 23, 2011

Related U.S. Application Data
(63) Continuation-in-part of application No. 13/236,601, filed on Sep. 19, 2011, now abandoned.

(51) Int. Cl. C23C 16/26; C23C 16/04; C23C 16/455; C23C 16/52; B82Y 40/00

(52) U.S. Cl. 427/249.1; 118/719; 118/712; 118/713; 977/842; 977/843

(57) ABSTRACT

An apparatus for growing carbon nanostructures (CNSs) on a substrate can include at least two CNS growth zones with at least one intermediate zone disposed therebetween and a substrate inlet before the CNS growth zones sized to allow a spoolable length substrate to pass therethrough.

### CROSS-REFERENCE TO RELATED APPLICATIONS

The present application claims the benefit of priority under 35 U.S.C. §119 as a continuation-in-part of U.S. patent application Ser. No. 13/236,601, “APPARATUSES AND METHODS FOR LARGE-SCALE PRODUCTION OF HYBRID FIBERS CONTAINING CARBON NANOSTRUCTURES AND RELATED MATERIALS,” filed on Sep. 19, 2011.

### STATEMENT REGARDING FEDERALLY SPONSORED RESEARCH OR DEVELOPMENT

Not applicable.

### FIELD OF THE INVENTION

The present invention generally to carbon nanostructures, and, more specifically, large scale production of carbon nanostructures.

### BACKGROUND

Current carbon nanotube (CNT) synthesis techniques can provide bulk quantities of “loose” CNTs for use in a variety of applications. These bulk CNTs can be used as a modifier or dopant in composite systems, for example. Such modified composites typically exhibit enhanced properties that represent a small fraction of the theoretical improvements expected by the presence of CNTs. The failure to realize the full potential of CNTs enhancement is related, in part, to the inability to dope beyond low percentages of CNTs (1-4%) in the resulting composite along with an overall inability to effectively disperse the CNTs within the structure. This low loading, coupled with difficulties in CNT alignment and CNT-to-matrix interfacial properties figure in the observed marginal increases in composite properties, such as mechanical strength, compared to the theoretical strength of CNTs. Besides the physical limitation of bulk CNTs incorporation, the price of CNTs remains high due to process inefficiencies and post processing required to purify the end CNT product. Similar limitations have been observed with the production and application of other carbon nanostructures (CNSs), like graphene.

One approach to overcome the above deficiencies, would be to develop techniques that grow CNSs directly on useful substrates, such as fibers, which can be used to organize the CNSs and provide a reinforcing materials in a composite. Progress has been made to grow CNSs on fibers in a nearly continuous fashion; however, none of these techniques have yet been successful at growing CNSs at a rate that is viable for commercial production.

In view of the foregoing, continuous production of CNS on substrates at a commercial level would be of substantial beneficial in the art. The present invention satisfies this need and provides related advantages as well.

### SUMMARY

In general, embodiments disclosed herein relate to apparatuses capable of continuous CNS synthesis on spoolable length substrates.

In certain embodiments, apparatuses for growing CNSs can include at least two CNS growth zones with at least one intermediate zone disposed therebetween; and a substrate inlet before the CNS growth zones sized to allow a spoolable length substrate to pass therethrough.

In certain embodiments, apparatuses for growing CNSs can include at least two CNS growth zones, wherein each CNS growth zone has a cross-sectional area less than about 600 times greater than a substrate cross-sectional area to be passed therethrough; at least one intermediate zone disposed between the at least two CNS growth zones; and a substrate inlet before the CNS growth zones sized to allow a spoolable length substrate to pass therethrough.

In certain embodiments, systems for growing CNSs can include at least one apparatus that includes at least two CNS growth zones along a substrate path with at least one intermediate zone disposed therebetween; at least one winder operably capable of maintaining a spoolable length substrate along the substrate path; and at least one motor operably connected to the winder.

In certain embodiments, methods for growing CNSs can include transporting at least a portion of a spoolable length substrate along a substrate path that includes at least two CNS growth zones and at least one intermediate zone disposed therebetween; heating at least the CNS growth zones; and passing a feed gas through at least the CNS growth zones.

The foregoing has outlined rather broadly the features of the present disclosure in order that the detailed description that follows can be better understood. Additional features and advantages of the disclosure will be described hereinafter, which form the subject of the claims.

### BRIEF DESCRIPTION OF THE DRAWINGS

For a more complete understanding of the present disclosure, and the advantages thereof, reference is now made to the following descriptions to be taken in conjunction with the accompanying drawings describing specific embodiments of the disclosure, wherein:

FIG. 1 shows a schematic of a nonlimiting example of an apparatus for growing carbon nanostructures in accordance with some embodiments of the present disclosure;

FIG. 2 shows a schematic of a nonlimiting example of an apparatus for growing carbon nanostructures in accordance with some embodiments of the present disclosure;

FIG. 3 shows a schematic of a nonlimiting example of an apparatus for growing carbon nanostructures in accordance with some embodiments of the present disclosure;

FIG. 4 shows a schematic of a nonlimiting example of a system comprising an apparatus for growing carbon nanostructures in accordance with some embodiments of the present disclosure;

FIG. 5 shows a dynamic snapshot of a substrate passing through an apparatus for growing carbon nanostructures;

FIG. 6 shows a dynamic snapshot and micrographs of a substrate passing through an apparatus for growing carbon nanostructures;

FIG. 7 shows a dynamic snapshot of a substrate passing through an apparatus for growing carbon nanostructures;

FIG. 8 shows an illustrative temperature profile observed in an apparatus for growing carbon nanostructures;

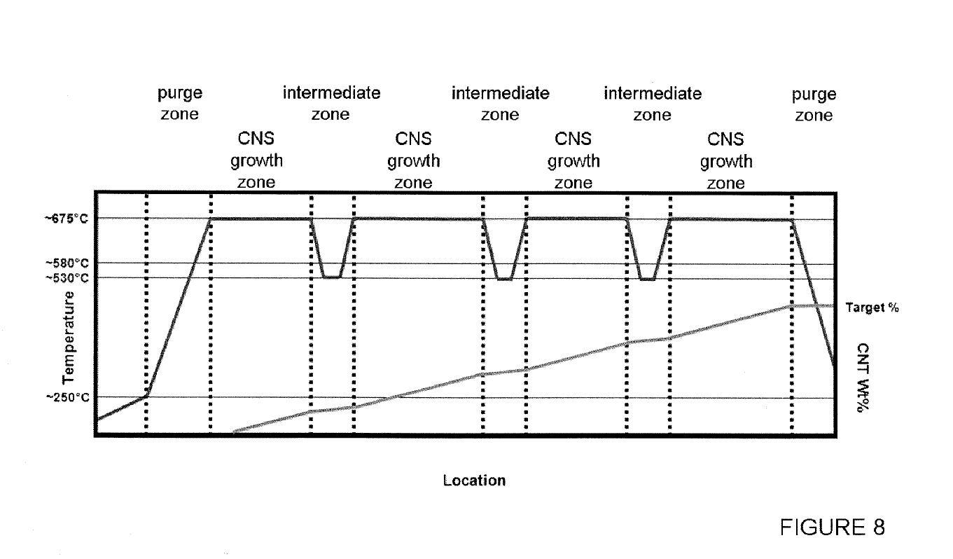

FIG. 9 shows an illustrative chart demonstrating the production of carbon nanostructures as a function of nitrogen flow rate; and

FIG. 10 shows an illustrative chart demonstrating the production of carbon nanostructures as a function of preheating the feed gas to various temperatures.

FIG. 11 shows an illustrative chart demonstrating the production of carbon nanostructures with different enclosure materials.

FIG. 12 shows an illustration of a nonlimiting example of a concentric enclosure configuration.

FIG. 13 shows an illustrative chart of carbon nanostructure production over a long-term run.

FIG. 14 shows an illustrative, nonlimiting example of a CNS growth zone cross-section having multiple substrate paths.

FIG. 15 shows an electron micrograph of a nonlimiting example of a CNS infused carbon fiber.

### DETAILED DESCRIPTION

The present disclosure is directed, in part, to an apparatus for preparing carbon nanostructures. The present disclosure is also directed, in part, to methods for growing carbon nanostructures on a substrate.

Apparatuses of the present invention generally include at least two carbon nanostructure (CNS) growth zones with an intermediate zone disposed therebetween. In some embodiments, the at least two CNS growth zones can be in series with at least one intermediate zone. Further, the apparatuses are configured to allow for a spoolable length substrate to pass along a substrate path through the CNS growth zones and the intermediate zones. In some embodiments, the apparatuses can take the form of an open ended, atmospheric, to slightly higher than atmospheric pressure, small cavity, chemical vapor deposition (CVD) CNS growth system. CNSs can be grown via CVD, or a like CNS growth process, at atmospheric pressure and at elevated temperature (typically in the range of about 550° C. to about 800° C.) in an apparatus of the present invention. The fact that the synthesis can occur at atmospheric pressure is one factor that facilitates the incorporation of the apparatuses into a continuous processing system for CNS-on-fiber synthesis. Additionally, using the apparatuses of the present disclosure, CNS growth occurs in seconds, as opposed to minutes (or longer) as is common in the art, which enables using the apparatus disclosed herein in a continuous processing line. Numerous apparatus configurations facilitate such continuous synthesis.

As used herein, the term “substrate path” refers to any path that a substrate follows through the apparatus.

As used herein, the term “zone” refers to a section along the substrate path of an apparatus that is configured to have substantially the same conditions during operation (e.g., temperature, feed gas composition, and pressure). With respect to feed gas composition, one of ordinary skill in the art, with the benefit of this disclosure, will understand that feed gas composition changes as the feed gas, or components thereof, react, and that changes in feed gas composition as referred here refers to actively changing the feed gas composition, for example, by introducing a new feed gas, additional feed gas, or changed concentration of feed gas, or components thereof. One of ordinary skill in the art, with the benefit of this disclosure, will understand there will be a variation in the conditions at the edges of a zone as operational conditions transition between adjacent zones. It should be noted that having two similarly named zones along the substrate path does not necessarily signify the conditions at both zones are the same. Further, a zone is configured as a result of the apparatus design and configuration, e.g., placement of heaters and placement of gas inlets.

As used herein, the term “CNS growth zone” refers to a zone, that while in operation, is under conditions favorable for CNS growth.

As used herein, the term “intermediate zone” refers to a zone, that while in operation, is under conditions less favorable for CNS growth relative to the CNS growth zone. That is, the CNS growth rate in an intermediate zone is less than the CNS growth rate in a CNS growth zone, if CNS growth occurs at all in the intermediate zone. Other processes can take place in an intermediate zone that can facilitate CNS growth in a CNS growth zone, as described further herein.

As used herein, the term “carbon nanostructures” (CNS, plural CNSs) refers to a structure that is less than about 100 nm in at least one dimension and substantially made of carbon. Carbon nanostructures can include graphene, fullerenes, carbon nanotubes, bamboo-like carbon nanotubes, carbon nanohorns, carbon nanofibers, carbon quantum dots, and the like. Further, CNSs can be present as an entangled and/or interlinked network of CNSs. Interlinked networks can contain CNSs that branch in a dendrimeric fashion from other CNSs. Interlinked networks can also contain bridges between CNSs, by way of nonlimiting example, a carbon nanotube can have a least a portion of a sidewall shared with another carbon nanotube.

As used herein, the term “graphene” will refer to a single-or few-layer (e.g., less than 10 layer) two-dimensional carbon sheet having predominantly sp² hybridized carbons. In the embodiments described herein, use of the term graphene should not be construed to be limited to any particular form of graphene unless otherwise noted.

As used herein, the term “carbon nanotube” will refer any of a number of cylindrically-shaped allotropes of carbon of the fullerene family including single-walled carbon nanotubes (SWNTs), double-walled carbon nanotubes (DWNTs), and multi-walled carbon nanotubes (MWNTs). Carbon nanotubes can be capped by a fullerene-like structure or open-ended. Carbon nanotubes can include those that encapsulate other materials.

As used herein the term “spoolable dimensions” refers to substrates having at least one dimension that is not limited in length, allowing for the material to be stored on a spool or winder. Substrates of “spoolable dimensions” have at least one dimension that indicates the use of either batch or continuous processing for CNS infusion as described herein. One substrate of spoolable dimensions that is commercially available is exemplified by AS4 12 k carbon fiber tow with a tex value of 800 (1 tex=1 g/1,000 m) or 620 yard/lb (Grafil, Inc., Sacramento, Calif.).

As used herein, the term “feed gas” refers to a gas composition for growing CNSs. Feed gas can include feedstock gases, carrier gases, auxiliary gases, or any combination thereof useful in growing CNS. As used herein, the term “feedstock gas” refers to any carbon compound gas (e.g., acetylene, ethylene, methane, carbon monoxide, carbon dioxide, and the like), solid, or liquid (e.g., methanol) that can be volatilized, nebulized, atomized, or otherwise fluidized and is capable of dissociating at high temperatures in the presence of a catalyst into at least some free carbon radicals and which, in the presence of a suitable catalyst, can form CNSs on the substrate. In some embodiments, feed gas can comprise acetylene, ethylene, methanol, methane, propane, benzene, natural gas, or any combination thereof. The term “carrier gas” refers to an inert gases, e.g., nitrogen and argon. The term “auxiliary gas” refers to additional gases, solids, or liquids that can be volatilized, nebulized, atomized, or otherwise fluidized that may be advantageously included in the feed gas composition, e.g., hydrogen, water, or ammonia. For example, auxiliary gases can aid in soot inhibition and/or catalyst reduction The feed gas typically contains a feedstock gas in a range from between about 0.1% to about 50% of the total mixture.

As used herein, the term “substrate” is intended to include any material upon which CNSs can be synthesized and can include, but is not limited to, a carbon fiber, a graphite fiber, a cellulosic fiber, a glass fiber, a metal fiber (e.g., steel, aluminum, etc.), a metallic fiber, a ceramic fiber, a metallic-ceramic fiber, an aramid fiber, or any substrate comprising a combination thereof. The substrate can include fibers or filaments arranged, for example, in a fiber tow (typically having about 1000 to about 12,000 fibers) as well as planar substrates such as fabrics, tapes, or other fiber broadgoods (e.g., veils, mats, and the like), and materials upon which CNSs can be synthesized.

As used herein, the term “nanoparticle” (NP, plural NPs), or grammatical equivalents thereof, refers to particles sized between about 0.1 to about 100 nanometers in equivalent spherical diameter, although the NPs need not be spherical in shape. Nanoparticles composed, at least in part, of a transition metal can serve as catalysts for CNS growth on the substrates.

As used herein, the term “transition metal” refers to any element or alloy of elements in the d-block of the periodic table (Groups 3 through 12), and the term “transition metal salt” refers to any transition metal compound such as, for example, transition metal oxides, carbides, nitrides, acetates, citrates, and the like. Illustrative transition metals that form catalytic nanoparticles suitable for synthesizing carbon nanotubes include, for example, Ni, Fe, Co, Mo, Cu, Cr, Pt, Pd, Au, Ag, alloys thereof, salts thereof, and mixtures thereof.

As used herein, the term “infused” means chemically or physically bonded and “infusion” means the process of bonding. The particular manner in which a CNS is “infused” to a substrate is referred to as a “bonding motif.”

As used herein, the term “material residence time” refers to the amount of time a discrete point along a substrate of spoolable dimensions is exposed to CNS growth conditions during the CNS infusion processes described herein. This definition includes the residence time when employing multiple CNS growth zones.

As used herein, the term “linespeed” refers to the speed at which a substrate of spoolable dimensions can be fed through the CNS growth processes described herein, where linespeed is a velocity determined by dividing CNS growth zone(s) length by the material residence time.

As used herein, the terms “sizing agent” or “sizing,” collectively refer to materials used in the manufacture of fiber materials that act as a coating to protect the integrity of the fiber material, to provide enhanced interfacial interactions between the fiber material and a matrix material, and/or to alter and/or to enhance certain physical properties of the fiber material.

As used herein, the term “uniform in length” refers to a condition in which carbon nanotubes have lengths with tolerances of plus or minus about 20% or less of the total carbon nanotube length, for carbon nanotube lengths ranging between about 1 μm to about 500 μm. At very short carbon nanotube lengths (e.g., about 1 μm to about 4 μm), the tolerance can be plus or minus about 1 μm, that is, somewhat more than about 20% of the total carbon nanotube length.

As used herein, the term “uniform in density distribution” refers to a condition in which the carbon nanotube density on a fiber material has a tolerance of plus or minus about 10% coverage over the fiber material surface area that is covered by carbon nanotubes.

It should be noted that reference numbers will be used to generally identify systems, apparatuses, elements or components thereof, and elements or components used in conjunction therewith. Like elements in figures shown herein will be referred to by the same reference number, with the letter indicating referral to a particular figure. When not referring to a particular figure, the letter designation of the component or element described will be omitted.

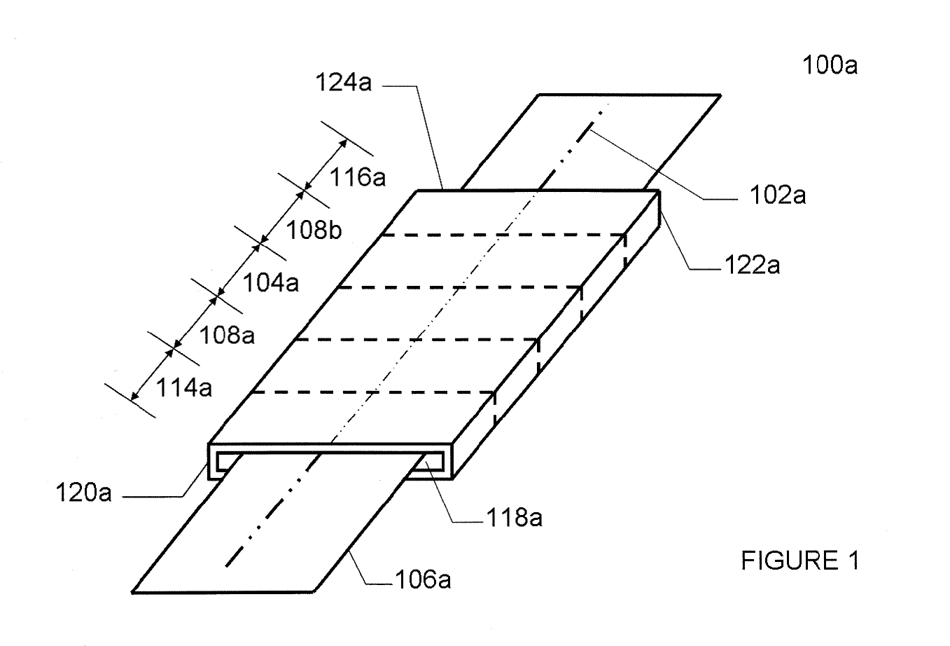

FIG. 1 shows a schematic of a nonlimiting example of an apparatus for growing carbon nanostructures in accordance with some embodiments of the present disclosure. Apparatus 100a is designed to allow for substrate 106a to pass through along substrate path 102a. Apparatus 100a can be open to the atmospheric environment during operation, with first end 120a and second end 124a, such that substrate 106a enters apparatus 100a through substrate inlet 118a at first end 120a: passes through first end zone 114a, CNS growth zone 108a, intermediate zone 104a, CNS growth zone and 108b, second end zone 116a; and exits apparatus 100a through substrate outlet 122a in second end 124a.

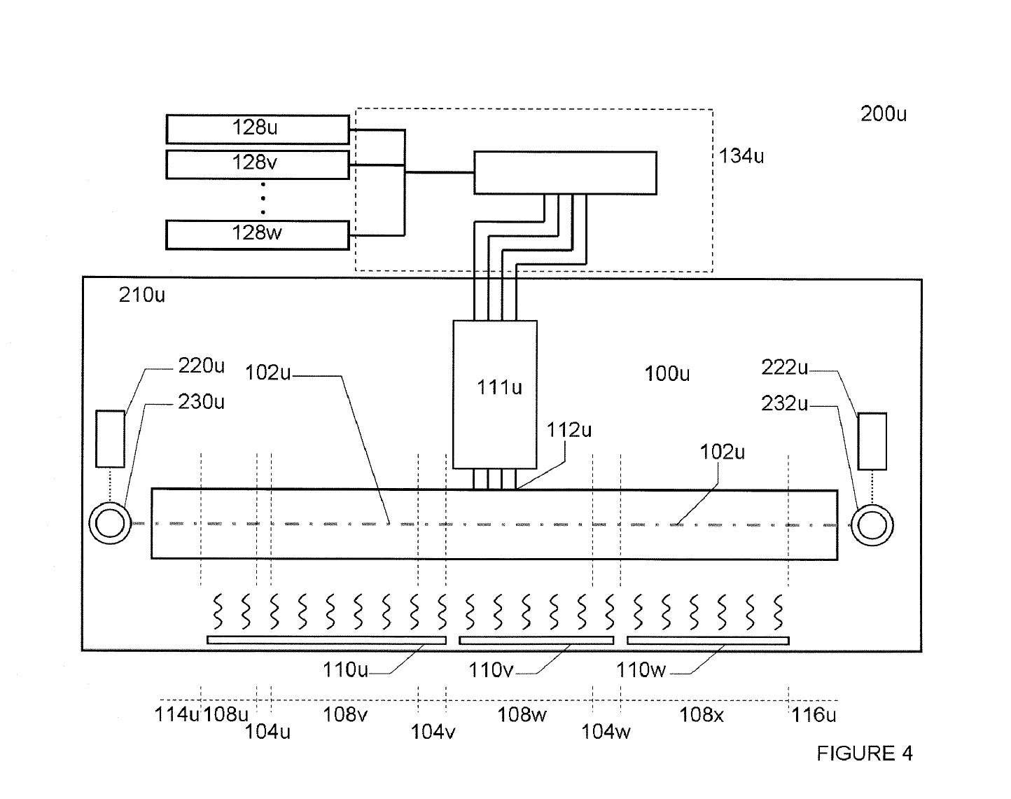

Apparatus 100 allows for the seamless transfer of substrate 106 into and out of CNS growth zones 108 and intermediate zone 104, obviating the need for batch runs. An integrated system 200 (like that shown in FIG. 4) can be a system where spoolable length substrate 106 effectively passes through apparatus 100 which has established conditions for rapid CNS growth in real time as substrate 106 continually moves through apparatus 100 to produce CNS infusion on substrate 106. The ability to do this continuously and efficiently at a high linespeed, while controlling parameters such as CNS length, density, and other characteristics has not been reliably achieved.

Apparatus 100 can include substrate inlet 118 sized to allow spoolable length substrate 106 to continually pass therethrough along substrate path 102, allowing for the synthesis and growth of CNSs directly on substrate 106. Specifically, FIG. 1 illustrates a nonlimiting example of apparatus 100a with separate substrate inlet 118a and substrate outlet 122a. However, in some embodiments, substrate inlet 118 and substrate outlet 122 can be one in the same, e.g., when substrate path 102 includes a turn.

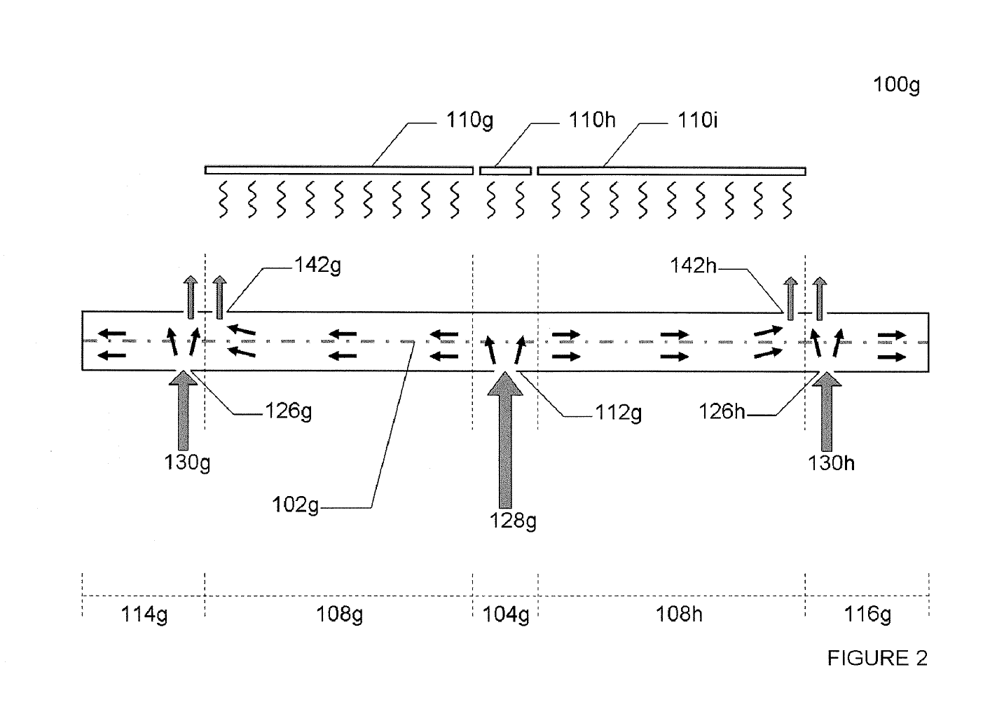

In some embodiments, apparatus 100 can be an open-air, continuous operation, flow-through chamber. As used herein, the term “open-air” refers generally to not being completely enclosed, e.g., apparatus 100 can be open at both ends 120 and 124. Further, apparatus 100 can include end zones 114 and 116 at ends 120 and 124, respectively. End zones can serve a variety of purposes including, but not limited to, preventing unwanted mixing of feed gas 128 with the outside atmospheric environment; preventing unintended oxidation and damage to the catalyst, substrate 106, and/or CNS material; cooling feed gas 128 (shown in FIG. 2); or any combination thereof. By way of nonlimiting example, end zones 114 and 116 can be actively cooled with the introduction of a carrier gas. By way of another nonlimiting example, end zones 114 and 116 can be have a length suitable for passive cooling of gases and/or substrates 106 passing therethrough.

Apparatus 100 can be a multi-zone apparatus with two or more CNS growth zones 108 with at least one intermediate zone 104 disposed therebetween. FIG. 1 illustrates a nonlimiting example of apparatus 100a with two CNS growth zones 108a and 108b with a single intermediate zone 104a disposed therebetween. In some embodiments, apparatus 100 can include three CNS growth zones 108 and one intermediate zone 104 disposed between two of the three CNS growth zones 108, i.e., 108-108-104-108 or 108-104-108-108. Further, in some embodiments, apparatus 100 can contain more than one intermediates zone 104 disposed between two or more CNS growth zones 108 in any configuration. By way of nonlimiting examples, apparatus 100 can be configured for any of the following along substrate path 102:

(a) 108-104-108-104-108;

(b) 108-104-104-104-108;

(c) 108-104-108-104-108-104-108-104-108;

(d) 108-108-108-104-104-108-104-108; or

(e) 108-108-108-108-108-104-108-108-108-108-108.

In some embodiments, apparatus 100 can include additional zones that are specifically designed to activate catalyst particles. In some embodiments, activation can take place via reduction of the catalyst. In such embodiments, a catalyst activation zone can be placed between first end zone 114 and CNS growth zone 108. Alternatively, the catalyst activation zone can be placed just before first end zone 114 (not shown). Additionally, intermediate zone 104 can be configured to be a catalyst re-activation zone.

Each CNS growth zone 108 is in thermal communication with at least one growth heater 110 and in fluid communication with at least one feed gas inlet 112 and at least one exhaust port 142. FIG. 2 shows a schematic of a nonlimiting example of an apparatus for growing carbon nanostructures in accordance with some embodiments of the present disclosure. Referring now to FIG. 2, apparatus 100g comprises two CNS growth zones 108g and 108h, one intermediate zone 104g, and two end zones 114g and 116g along substrate path 102g. Further, apparatus 100g includes three heaters 110g-i in thermal communication with CNS growth zones 108g and 108h and intermediate zone 104g. In some embodiments, each zone can be in thermal communication with individual heaters 110. In some embodiments, a single zone can be in thermal communication with multiple heaters 110. In some embodiments, multiple zones can be in thermal communication with one heater 110. In some embodiments, any combination of the aforementioned three configurations can be employed in apparatus 100.

Referring again to FIG. 2, apparatus 100g comprises one feed gas inlet 112g where feed gas 128g enters at intermediate zone 104g. In some embodiments, feed gas inlet 112 can be configure to introduce feed gas 128 into at least one intermediate zone 104, at least one CNS growth zone 108, or any combination thereof. Further, more than one feed gas 128 can be introduced via more than one feed gas inlet 112.

Referring again to FIG. 2, apparatus 100g comprises two end zones 114g and 116g that provide the same function. As feed gas 128g from CNS growth zone 108g and 108h exits apparatus 100g, end zones 114g and 116g are zones with a continuous flow of carrier gas 130g and 130h introduced via carrier gas inlets 126g and 126h, respectively. End zones 114g and 116g act to buffer CNS growth zones 108g and 108h from the external environment. This helps to prevent unwanted mixing of feed gas 128g with the outside atmospheric environment, which could cause unintended oxidation and damage to substrate 106 (not shown) or CNS material. Apparatus 100g further comprises exhaust ports 142g and 142h placed between end zones 114g and 116g and CNS growth zone 108g and 108h, respectively. In such embodiments, gas does not substantially mix between CNS growth zones 108g and 108h and end zones 114g and 116g, respectively, but instead exhausts to the atmospheric environment through exhaust ports 142g and 142h.

In some embodiments, end zones 114 and 116 can provide a cool carrier gas 130 to ensure reduced temperatures as substrate 106 enters/exits CNS growth zones 108. In some embodiments, carrier gas 130 can include an auxiliary gas. In some embodiments, end zones 114 and 116 can be at a sufficient length passively transition the temperature of substrate 106 entering and/or exiting CNS growth zones 108. In some embodiments, end zones 114 and 116 can be optionally preheated by heaters 110 or cooled. Further, end zones 114 and 116 can be insulated from CNS growth zone 108 to prevent excessive heat loss or transfer from heated CNS growth zone 108. In some embodiments not comprising exhaust ports 142, gases introduced into apparatus 100 can exit apparatus 100 via ends 120 and 124.

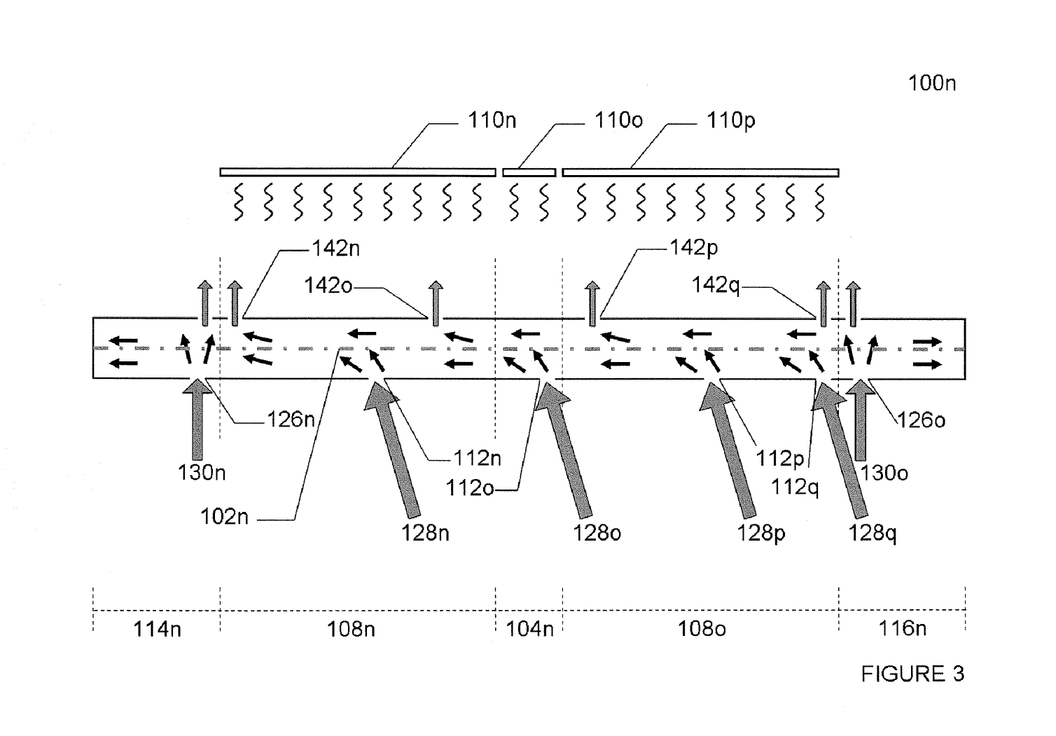

FIG. 3 shows a schematic of a nonlimiting example of an apparatus for growing carbon nanostructures in accordance with some embodiments of the present disclosure. Referring now to FIG. 3, apparatus 100n comprises two CNS growth zones 108n and 108o, one intermediate zone 104n, and two end zones 114n and 116n along substrate path 102n. Further, apparatus 100n comprises three heaters 110n-p in thermal communication with CNS growth zones 108n and 108o and intermediate zone 104n: Apparatus 100n also comprises three feed gas inlets 112n-q and two carrier gas inlets 126n and 126o for introduction of feed gas 128n-q and carrier gas 130n and 130o, respectively. Apparatus 100n also comprises exhaust ports 142n-q.

FIG. 3 illustrates that in some embodiments, feed gas 128 (e.g., 128n-q) can be introduced directionally. In some embodiments, feed gas inlets 112 and exhaust ports 142 can be configured relative to substrate path 102 to achieve feed gas 128 flow in a desired direction. In some embodiments, feed gas 128 can flow in different directions in different zones and/or within a single zone. In some embodiments, feed gas 128 flow is substantially in the same direction through CNS growth zone 108 and intermediate zone 104. One of ordinary skill in the art, with the benefit of this disclosure, will understand that adjusting the spacing, size, and frequency of feed gas inlet 112 and exhaust port 142 can impact the growth of CNSs, e.g., when using acetylene in feed gas 128 replenishing feed gas 128 often can be important at higher temperatures to reduce the adverse impact that gaseous acetylene cracking byproducts can have on CNS growth. Further, one of ordinary skill in the art will understand that at as carbon from feed gas 128 is converted to CNS material, the concentration of carbon in feed gas 128 reduces. Properly spaced inlets can increase the CNS production efficiency. Higher line speed further magnify this mass balance issue of carbon in feed gas 128 to carbon in CNS. Carbon in feed gas 128 is consumed to a greater degree because faster line speed expose more catalyst to carbon in feed gas 128. Further, high line speeds may benefit from directional flow of feed gas 128. Specifically, the relative velocity change from gas flow with and against substrate 106 can significantly effect the gas-to-substrate relative residence time.

In some embodiments, apparatus 100 may comprise additional components and/or elements involved with gas introduction and removal. Suitable components include gas diffusers, feed gas inlet manifolds (see FIG. 4), and exhaust manifolds. Said components have been previously described in U.S. patent application Ser. Nos. 12/714,389 and 12/832,919, the entire disclosures of which are herein incorporated by reference.

CNS growth zones 108 and intermediate zones 104 can be at different conditions. In some embodiments, at least two CNS growth zones 108 of apparatus 100 can be at different conditions. Suitable conditions to manipulate include, but are not limited to, temperature, feed gas flow rate, and feed gas composition. Such conditions can be manipulated through configurations of apparatus 100 including, but not limited to, placement of heaters 110, placement of feed gas inlets 112, placement of feed gas heaters 111, and the like. By way of nonlimiting example, CNS growth zone 108 can be held at about 675° C. while intermediate zone 104 is held at about 530° C. Another nonlimiting example can include introducing feed gas 128 at a reduced temperature thereby defining intermediate zone 104.

Additionally apparatus 100 can include a component (not shown) to achieve different conditions between zones. Suitable conditions that can be achieved via a component including, but not limited to, a magnetic field, an electric field, the addition of radical or molecular species, and any combination thereof. By way of nonlimiting example, a hot filament can be placed in the feed gas flow stream within intermediate zone 104 to convert hydrogen in the feed gas to molecular hydrogen. In some embodiments, intermediate zone 104 can be held at conditions that are favorable for CNS growth. In some embodiments, intermediate zone 104 can be held at conditions that allow for slower growth than conditions in CNS growth zone 108. In some embodiments, intermediate zone 104 can be held at conditions that are favorable for reactivating the catalyst and/or stabilizing the catalyst.

In some embodiments, a continuous process for growth of CNSs on spoolable length substrates can achieve a linespeed between about 1 m/min to about 50 m/min or greater. In some embodiments, linespeed can range from about 15 cm/min to about 50 m/min; about 1.5 m/min to about 50 m/min; or about 5 m/min to about 60 m/min. One of ordinary skill in the art, with the benefit of this disclosure, should understand that the upper limit for linespeed is a function of the configuration of apparatus 100 and the desired CNS characteristics, e.g., length and density. Therefore, linespeeds of greater than about 60 m/min are applicable.

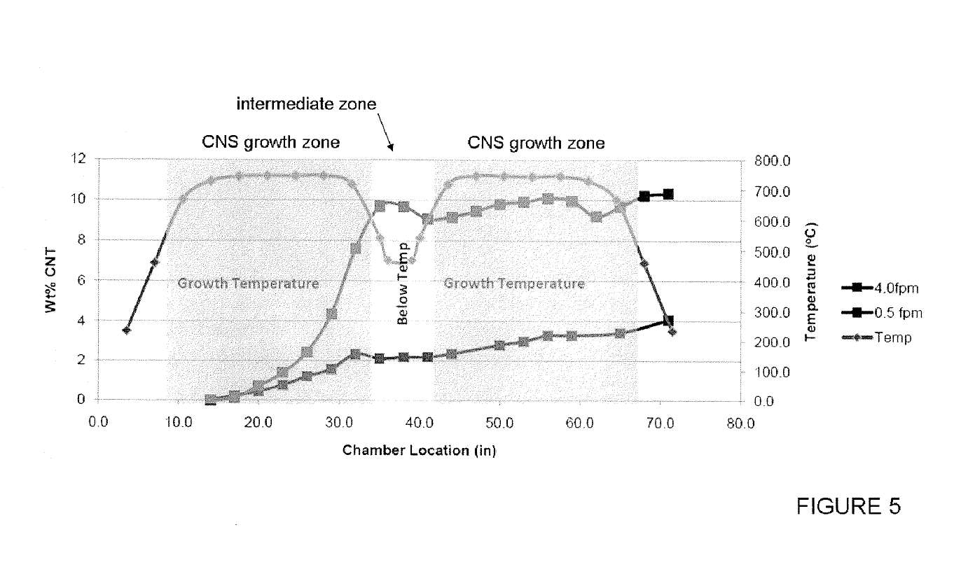

Linespeed can be a determining factor that can dictate the processes that occur within CNS growth zone 108 and intermediate zone 104. That is, linespeed determines residence time, and residence time has a direct impact on the amount and/or length of CNS growth and the efficacy of catalyst reactivation and/or stabilization. By way of nonlimiting example, where CNS growth zone 108 is 400 cm long and operating at a 750° C. growth temperature, the process can be run with a linespeed of about 8 m/min to about 16 m/m in to produce, for example, carbon nanotube (CNTs) having a length between about 1 micron to about 10 microns. The process can also be run with a linespeed of about 4 m/min to about 8 m/min to produce, for example, CNTs having a length between about 10 microns to about 80 microns. The process can be run with a linespeed of about 1 m/min to about 4 m/min to produce, for example, CNTs having a length between about 80 microns to about 200 microns. In some embodiments, a linespeed of up to at least 60 m/min can be used for a continuous process for infusion. Another nonlimiting example of linespeed impact includes where intermediate zone 104 is 20 cm long an operating at 475° C., a linespeed of about 15 cm/min can “kill” the catalyst, i.e., cause the catalyst to not be able to grow further CNS in a subsequent CNS growth zone. At a linespeed of about 1.25 m/min, for example, the catalyst can remain “active” for further growth in a subsequent CNS growth zone 108. Such an example of the dependence of CNS growth rate upon linespeed is illustrated in FIG. 5.

The amount and/or length of CNS growth is not tied only to linespeed and temperature; the flow rate and composition of feed gas 128 can also influence CNS amount and/or length. Feed gas 128 with higher carbon concentrations provide more carbon to produce CNS, however, excess carbon can be detrimental to the catalyst, i.e., overload with carbon and render it inactive to CNS growth. Further, the flow rate of feed gas 128 can assist in replenishing carbon available for CNS production. This can be especially important for carbon sources that decompose in the presence of a catalyst at the temperature of CNS growth zone 108 and/or carbon sources that react with the walls of CNS growth zone 108, e.g., acetylene. By way of nonlimiting example, a flow rate consisting of less than 1% carbon feedstock in inert gas at high linespeeds (8 m/min to 16 m/min) can result in CNTs having a length between 1 micron to about 5 microns. A flow rate consisting of more than 1% carbon feedstock in inert gas at high linespeeds (8 m/min to 16 m/min) can result in CNTs having length between 5 microns to about 10 microns. Resulting growth rates for this continuous CNS growth system range depend on at least temperature, gases used, substrate residence time, and catalyst. However, for example, CNT and CNS web growth rates on the range of 0.01-10 microns/second are possible.

CNS growth zone 108 and intermediate zone 104 can be formed or otherwise bound by an enclosure of metal, metal alloy, refractory glass, ceramic, composite, any mixture thereof, and any combination thereof. By way of nonlimiting example, the enclosure may include stainless steel, titanium, carbon steel, INCONEL® (nickel-chromium-based superalloys, available from Special Metals Corporations), INVAR® (a nickel steel alloy, available from Special Metals Corporations), other high temperature metals, non-porous ceramics, quartz, and mixture thereof, and any combination thereof. CNS growth zones 108 and intermediate zone(s) 104 along substrate path 102 can be a single enclosure.

In some embodiments, CNS growth zone 108 and intermediate zone 104 can be formed or otherwise bound by a concentric enclosure configuration, i.e., an inner enclosure with at least one enclosure thereabout. In some embodiments, the inner enclosure can be removable. The various enclosures of a concentric enclosure configuration may be of different enclosure materials listed above. By way of nonlimiting example, a quartz tube can be placed in a stainless steel enclosure. Concentric enclosure configurations can have many benefits including, but not limited to, removal and cleaning of the enclosure proximal to substrate path 102, variation of enclosure material along substrate path 102, and overcoming expensive apparatus 100 costs (e.g., a full quartz enclosure with multiple feed gas inlets 112 versus inserting quartz tubing in a stainless steel enclosure between gas inlets). By way of nonlimiting example, apparatus 100 may comprise at least two CNS growth zone 108 having a concentric enclosure configuration for of stainless steel with a quartz enclosure disposed therein, at least one intermediate zone 104 having an INCONEL® enclosure, and at least one feed gas inlet 112 of INCONEL® connected to the at least one intermediate zone 104. In such an example, quartz and INCONEL®, having about 5% iron, as the enclosure proximal to substrate path 102 produce less soot versus a stainless steel enclosure proximal to substrate path 102 having about 67% iron. One of ordinary skill in the art, with the benefit of this disclosure, would understand that the annular spacing within a concentric enclosure configuration should be minimized.

In some embodiments, CNS growth zone 108 and intermediate zone 104 can be formed or otherwise bound by a hybrid enclosure wherein only a portion of the enclosure along substrate path 102 has a concentric enclosure configuration. Generally, the descriptions of cross-sectional shapes, enclosure volumes, and cross-sectional area provided herein refer to the enclosure proximal to substrate path 102, e.g., the inner enclosure of a concentric enclosure configuration.

CNS growth zone 108 and intermediate zone 104 can be circular, rectangular, oval, or any number of polygonal or other geometrical variant cross-section based on the profile and size of substrate passing therethrough. In some embodiments, the cross-section of the zones can change in size and/or shape along the length of an individual zone or between zones. Such a change can be to affect flow rate within a zone, for example. Such a change can be to accommodate a component as described above.

An internal volume of CNS growth zone 108 or intermediate zone 104 can be compared with a volume of substrate 106 having a length substantially equal to a length of CNS growth zone 108 or intermediate zone 104. In some embodiments, CNS growth zone 108 is designed to have an internal volume of no more than about 10,000 times greater than the volume of substrate 106 disposed within CNS growth zone 108 or intermediate zone 104. In some embodiments, this number is greatly reduced to no more than about 4000 times, about 1000 times, or about 300 times. Similarly, cross-sectional areas of CNS growth zone 108 or intermediate zone 104 can be limited to about 10,000, 4000, 1000, 600, 400, or 300 times greater than a cross sectional area of substrate 106. One skilled in the art, with the benefit of this disclosure, will understand the lower limit of the cross-sectional area and internal volume of the CNS growth zone 108 and/or intermediate zone 104 to be sufficiently that which allows for substrate 106 with CNS infused thereto to pass therethrough, which depends on the final product. By way of nonlimiting example, cross-sectional areas of CNS growth zone 108 or intermediate zone 104 can be as low as 50 times greater than a cross sectional area of substrate 106. In some embodiments, the volume of CNS growth zone 108 or intermediate zone 104 is less than or equal to about 10000% of the volume of substrate 106 being fed therethrough. Without being bound by theory, reducing the size of CNS growth zone 108 or intermediate zone 104 ensures high probability interactions between feed gas 128 and substrate 106. Larger volumes result in excessive unfavorable reactions, e.g., in the gas phase and/or with the walls of the CNS growth zone enclosure. CNS growth zone 108 or intermediate zone 104 can range from dimensions as small as 1 millimeter to as large as over 1600 mm in the largest cross-sectional dimension. CNS growth zone 108 or intermediate zone 104 can have a rectangular cross-section and a volume of about 240 cm³ to as large as 150,000 cm³. In some embodiments, CNS growth zone 108 or intermediate zone 104 can have a cross-sectional area less than about 500 times greater than the cross-sectional area of substrate 106.

Temperature in CNS growth zone 108 and intermediate zone 104 can be controlled with imbedded thermocouples strategically placed on an interior surface thereof. Since CNS growth zone 108 and intermediate zone 104 have a small cross-sectional area, the temperature of the enclosure is nearly the same temperature as the gases inside. CNS growth zone 108 can be maintained between about 500° C. and about 1000° C. Intermediate zone 104 can be maintained between about room temperature and about 800° C.

Heaters 110 can be any suitable device capable of maintaining CNS growth zone 108, intermediate zone 104, and/or end zones 114 and 116 at about the operating temperature. Alternatively, or additionally, heaters 111 (shown in FIG. 4 as 111u) can preheat feed gas 128 and/or carrier gas 130. Any of heaters 110 and 111 can be used in conjunction with the various zones of apparatus 100. Heaters 110 and 111 can include long coils of gas line heated by a resistively heated element, and/or series of expanding tubes to slow down gas flow, which is then heated via resistive heaters (e.g., infrared heaters). Regardless of the method, gas can be heated from about room temperature to a temperature suitable for a desired result, e.g., from about 25° C. to about 800° C., or up to about 1000° C. or more. Temperature controls (not shown) can provide monitoring and/or adjustment of temperature within the various zones of apparatus 100. Measurements can be made at points (e.g., with a probe not shown) on plates, the enclosure, or other structures defining the various zones of apparatus 100. Because the cross-section of the various zones of apparatus 100 are relatively small, the temperature gradient across the height of the enclosure can be very small, and thus, measurement of temperature of the plates or the enclosure can accurately reflect the temperature within the various zones of apparatus 100.

In some embodiments, feed gas 128 and/or carrier gas 130 can be preheated by heater 111. In some embodiments, a single heater can be used to preheat feed gas 128 and carrier gas 130. In some embodiments, feed gas 128 can be preheated prior to introduction into at least one zone of apparatus 100.

Because substrate 106 has a small thermal mass, as compared with the various zones of apparatus 100, substrate 106 can assume the temperature of the various zones of apparatus 100 almost immediately. Thus, preheat can be left off to allow room temperature gas to enter the growth zone for heating by heaters 110. In some embodiments, only carrier gas is preheated. Other feed gas 128 can be added to carrier gas 130 after carrier gas preheater 132. This can be done to reduce long term sooting and clogging conditions that can occur in carrier gas preheater 132 over long times of operations. Preheated carrier gas can then enter feed gas inlet manifold 134. In some embodiments, a component of feed gas 128 can be heated prior to mixing with the other components of feed gas 128, e.g., nitrogen can be preheated to about 500° C. prior to mixing feed gas 128 to a final composition of 60% nitrogen, and 40% acetylene. It would be known by one skilled in the art with the benefit of this disclosure that any of the gases or components of the gas can be preheated.

Feed gas inlet manifold 134 provides a cavity for further gas mixing as well as a means for dispersing and distributing gas to all gas insertion points in CNS growth zone 108 and/or intermediate zone 104. In some embodiments where more than one feed gas 128 composition is used, more than one feed gas inlet manifold 134 can be used. In some embodiments, heater 110 can be incorporated within feed gas inlet manifold 134 so as to heat only some of the feed gas composition prior to mixing feed gas 128.

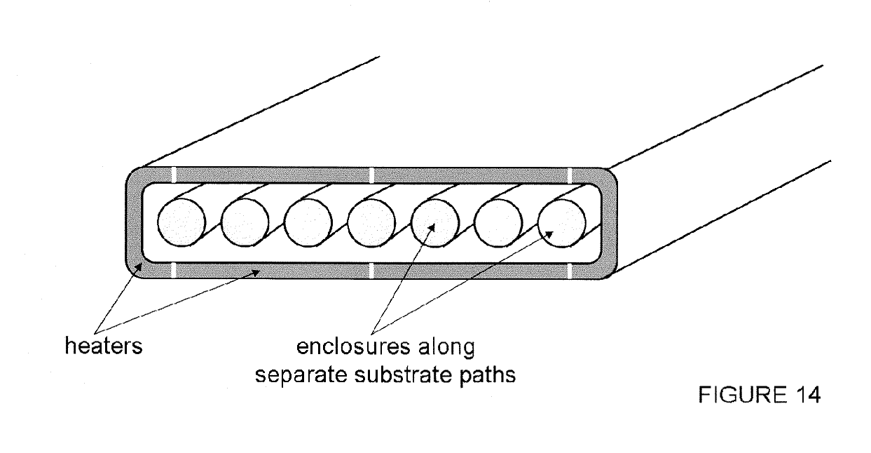

In some embodiments, multiple substrates 106 can pass through apparatus 100 at any given time, in a single enclosure, in multiple enclosures (e.g., FIG. 14), or any combination thereof Likewise, any number of heaters can be used either inside or outside a particular CNS growth zone 108 and/or intermediate zone 104.

In some embodiments, apparatus 100 allows for both a catalyst reduction and CNS growth to occur within CNS growth zone 108. Conventionally, the reduction step typically takes 1-12 hours to perform. The reduction process within apparatus 100 can be affected by a variety of factors including, but not limited to, the temperature, the catalyst composition, feed gas composition, and the feed gas flow rates, e.g., the amount of hydrogen available upon dissociation to reduce the catalyst.

System: FIG. 4 shows a schematic of a nonlimiting example of a system comprising an apparatus for growing carbon nanostructures in accordance with some embodiments of the present disclosure. Referring now to FIG. 4, in some embodiments, apparatus 100u of the present invention can be a component of system 200u that allows for spoolable length substrate 106u (not shown) to continuously pass through apparatus 100u along substrate path 102u. Apparatus 100u comprises four CNS growth zones 108u-x, three intermediate zones 104u-w, and two end zones 114u and 116u along substrate path 102u. Further, apparatus 100u includes three heaters 110u-w in thermal communication with the various zones of apparatus 100u. Apparatus 100u also comprises feed gas inlet 112u, heater 111u, and gas manifold 134u for mixing feed gases 128u-w. System 200u includes winders 220u and 222u; motors 230u and 232u; and enclosure 210u. In some embodiments, enclosure 210 is optional.

Winders 220 and 222 can be any structure that provides for spooling substrate 106 and maintaining substrate 106 along substrate path 102 through apparatus 100 including, but not limited to, pipes, tubes, rods, spindles, axles, wheels, cogs, and the like. Further, winders 220 and 222 can be of any suitable material including, but not limited to, plastics, metals, natural materials, composites, ceramics, and any combination thereof. Winders 220 and 222 can have any cross-sectional shape, including but not limited to, circular, oblong, polygonal, and any hybrid thereof Further, the cross-sectional area of winders 220 and 222 can change along the length of winders 220 and 222. It should be noted that winder 222 can be replaced with a tension apparatus to allow for collection of CNS-infused fibers in a non-wound form, e.g., chopped pieces, bales, and the like.

Motor 230 and 232 (e.g., 230u and 232u of FIG. 4) are operably connected to winder 220 and 222, respectively, to manipulate winder 220 and 222. Manipulation of winders 220 and 222 can include, but not be limited to, rotating, spinning, revolving, oscillating, wobbling, the like, and any combination thereof. Spoolable length substrate 106 is strung between winder 220 and 222 such spoolable length substrate 106 passes through apparatus 100 along substrate path 102. Motors 230 and 232 rotate winders 220 and 222 so as to move spoolable length substrate 106 continuously through apparatus 100. In some embodiments, winder 220 holds spoolable length substrate 106 prior to CNS infusion, spoolable length substrate 106 passes through apparatus 100 at conditions for CNS growth, and winder 222 collects spoolable length substrate 106 after CNS infusion. In some embodiments, spoolable length substrate 106 can be collected on winder 222 in a precise geometric pattern, in a random pattern, or any pattern therebetween. It should be noted that motor 230 and 232 can be one in the same. Winder 220 and 222 can be one in the same. Further, winder 220 and/or 222 can be multiple winders, e.g., spoolable length substrate 106 can be split before CNS infusion and be collected on more than on winder 222.

Optional enclosure 210 can provide a safety shield between an operator and portions of system 200. By way of nonlimiting examples, enclosure 210 can assist in containing feed gas 128, reducing the noise associated with running system 200, and/or providing a physical barrier to moving parts of system 200. In some embodiments, system 200 can have more than one enclosure 210 that are separate and/or contained within enclosure 210. Enclosure 210 can contain a portion or all of apparatus 100. Further, motor 230 and 232 and/or winder 220 and 222 can be contained within or outside enclosure 210.

In some embodiments, a portion of apparatus 100 can be contained within enclosure 210. In some embodiments, all of apparatus 100 can be contained within enclosure 210. In some embodiments, system 200 may contain more than one apparatus 100.

System 200 can optionally include additional components along substrate pat 102 for performing additional operations to spoolable length substrate 106 in continuous fashion, thereby extending the basic continuous process. Suitable components can include, but not be limited to, substrate splitters that produce multiple spoolable length substrates 106 from a single spoolable length substrate 106; substrate manipulators that the shape of spoolable length substrate 106 either before or after CNS infusion, i.e., flattening a CNS-infused fiber with a substantially round cross-section; catalyst deposition components that deposit materials on spoolable length substrate 106, e.g., CNS-forming catalysts or barrier coatings; removal components to remove materials from spoolable length substrate 106, e.g., sizing or CNSs; alignment components that align CNSs, e.g., magnetic fields and/or electrical fields; impregnation components that impregnate CNS-infused fibers with additional materials, e.g., polymers and/or metals; chopping components that chop CNS-infused fibers; and any combination thereof. It should be noted that system 200 capable of producing chopped CNS-infused fibers can collect the chopped CNS-infused fibers in a container, on a veil, and/or on a conveyor, such that winder 222 can be replaced with a tension apparatus.

System 200 can optionally include additional components operably connected to system 200 for monitoring varying aspects of system 200 and/or apparatus 100. In some embodiments, additional components can include, but not be limited to, components for analyzing CNS growth conditions; for analyzing CNS growth progress; and any combination thereof Suitable components include, but are not limited to, thermal sensors; gas sensors; gas analyzers like gas chromatographs; cameras; microscopes; in-line resistance monitors; and any combination thereof.

Other components system 200 can optionally contain include ventilation; insulation; gas flow controllers; other gas delivery equipment; and any combination thereof.

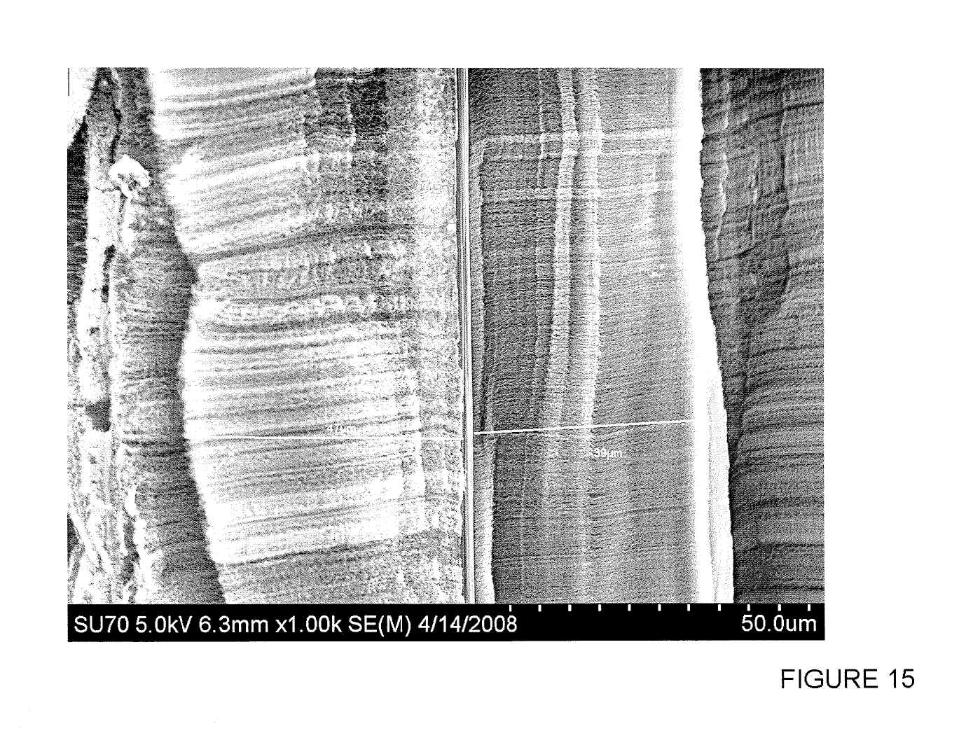

CNS Infused Fibers: FIG. 15 provides a scanning electron micrograph of a nonlimiting example of a CNS-infused carbon fiber. The illustrative embodiments described herein can be used with any type of substrate 106. In some embodiments, use of apparatus 100 of the present invention results in the production of CNS infused fiber. As used herein, the term “infused” means chemically or physically bonded and “infusion” means the process of bonding. Such bonding can involve direct covalent bonding, ionic bonding, pi-pi, and/or van der Waals force-mediated physisorption. For example, in some embodiments, the CNSs can be directly bonded to the substrate. Additionally, it is believed that some degree of mechanical interlocking occurs as well. Bonding can be indirect, such as the CNS infusion to the substrate via a barrier coating and/or an intervening transition metal nanoparticle disposed between the CNSs and substrate. In the CNS-infused substrates disclosed herein, the carbon nanostructures can be “infused” to the substrate directly or indirectly as described above. The particular manner in which a CNS is “infused” to a substrate is referred to as a “bonding motif.”

CNSs useful for infusion to substrates include, but are not limited to, single-walled CNTs, double-walled CNTs, multi-walled CNTs, graphene, and mixtures thereof. In some embodiments, the infused CNS is substantially single-wall nanotubes. In some embodiments, the infused CNS is substantially multi-wall nanotubes. In some embodiments, the infused CNS is a combination of single-wall and multi-wall nanotubes. There are some differences in the characteristic properties of single-wall and multi-wall nanotubes that, for some end uses of the fiber, dictate the synthesis of one or the other type of nanotube. For example, single-walled nanotubes can be semi-conducting or metallic, while multi-walled nanotubes are metallic.

The CNS-infused substrate can be tailored for the desired application of the CNS-infused substrate. Tailoring can be achieved by changes in the configuration of apparatus 100 and/or changes in the operational conditions of apparatus 100. CNS-infused substrates can be used for thermal and/or electrical conductivity applications, or as insulators. Further, CNS-infused substrate can be used to impart enhanced mechanical characteristics to a material.

In some aspects of the disclosure apparatus 100 can be used to produce CNS-infused fiber materials. Fibers suitable for infusion can include, but not be limited to, carbon fibers, glass fibers, metal fibers, ceramic fibers, and organic (e.g., aramid) fibers. Examples of a carbon fiber material include, but are not limited to, a carbon filament, a carbon fiber yarn, a carbon fiber tow, a carbon tape, a carbon fiber-braid, a woven carbon fabric, a non-woven carbon fiber mat, a carbon fiber ply, and other 3D woven structures. Carbon filaments include high aspect ratio carbon fibers having diameters ranging in size from between about 1 micron to about 100 microns. Tows include loosely associated bundles of untwisted filaments. As in yarns, filament diameter in a tow is generally uniform. Tows also have varying weights and the tex range is usually between 200 tex and 2000 tex. They are frequently characterized by the number of thousands of filaments in the tow, for example 12K tow, 24K tow, 48K tow, and the like. Carbon fiber tows are generally compactly associated bundles of filaments and are usually twisted together to give yarns. Yarns include closely associated bundles of twisted filaments. Each filament diameter in a yarn is relatively uniform. Yarns have varying weights described by their ‘tex,’ expressed as weight in grams of 1000 linear meters, or denier, expressed as weight in pounds of 10,000 yards, with a typical tex range usually being between about 200 tex to about 2000 tex. Carbon tapes are materials that can be assembled as weaves or can represent non-woven flattened tows. Carbon tapes can vary in width and are generally two-sided structures similar to ribbon. Processes of the present disclosure may be compatible with CNT infusion on one or both sides of a tape. CNT-infused tapes can resemble a “carpet” or “forest” on a flat substrate surface. Again, processes of the disclosure may be performed in a continuous mode to functionalize spools of tape. Carbon fiber-braids represent rope-like structures of densely packed carbon fibers. Such structures can be assembled from carbon yarns, for example. Braided structures can include a hollow portion or a braided structure can be assembled about another core material.

In some aspects of the disclosure, a number of primary fiber material structures can be organized into fabric or sheet-like structures. These include, for example, woven carbon fabrics, non-woven carbon fiber mat and carbon fiber ply, in addition to the tapes described above. Such higher ordered structures can be assembled from parent tows, yarns, filaments or the like, with CNSs already infused in the parent fiber. Alternatively, such structures can serve as the substrate for the CNS infusion processes described herein.

There are three types of fiber material which are categorized based on the precursors used to generate the fibers, any of which can be used in the present disclosure: Rayon, Polyacrylonitrile (PAN) and Pitch. Carbon fiber from rayon precursors, which are cellulosic materials, has relatively low carbon content at about 20% and the fibers tend to have low strength and stiffness. Polyacrylonitrile (PAN) precursors provide a carbon fiber with a carbon content of about 55%. Carbon fiber based on a PAN precursor generally has a higher tensile strength than carbon fiber based on other carbon fiber precursors due to a minimum of surface defects. Pitch precursors based on petroleum asphalt, coal tar, and polyvinyl chloride can also be used to produce carbon fiber. Although pitches are relatively low in cost and high in carbon yield, there can be issues of non-uniformity in a given batch.

The operation of disposing catalytic nanoparticles on the fiber material can be accomplished by a number of techniques including, for example, spraying or dip coating a solution of catalytic nanoparticles or by gas phase deposition, which can occur by a plasma process, for example. Thus, in some embodiments, after forming a catalyst solution in a solvent, the catalyst can be applied by spraying or dip coating the fiber material with the solution, or combinations of spraying and dip coating. Either technique, used alone or in combination, can be employed once, twice, thrice, four times, up to any number of times to provide a fiber material that is sufficiently uniformly coated with catalytic nanoparticles that are operable for formation of CNSs. When dip coating is employed, for example, a fiber material can be placed in a first dip bath for a first residence time in the first dip bath. When employing a second dip bath, the fiber material can be placed in the second dip bath for a second residence time. For example, fiber materials can be subjected to a solution of CNS-forming catalyst for between about 3 seconds to about 90 seconds depending on the dip configuration and linespeed. Employing spraying or dip coating processes, a fiber material with a catalyst surface density of less than about 5% surface coverage to as high as about 80% surface coverage can be obtained. At higher surface densities (e.g., about 80%), the CNS-forming catalyst nanoparticles are nearly a monolayer. In some embodiments, the process of coating the CNS-forming catalyst on the fiber material produces no more than a monolayer. For example, CNS growth on a stack of CNS-forming catalyst can erode the degree of infusion of the CNS to the fiber material. In other embodiments, transition metal catalytic nanoparticles can be deposited on the fiber material using evaporation techniques, electrolytic deposition techniques, and other processes known to those of ordinary skill in the art, such as addition of the transition metal catalyst to a plasma feedstock gas as a metal organic, metal salt or other composition promoting gas phase transport. In some embodiments, a catalyst precursor such as, for example, a transition metal salt can be deposited on the substrate. The catalyst precursor can subsequently be converted into an active catalyst upon exposure to CNS grown conditions without a separate catalyst activation step being used.

Because processes to manufacture CNS-infused fibers are designed to be continuous, a spoolable fiber material can be dip-coated in a series of baths where dip coating baths are spatially separated. In a continuous process in which nascent fibers are being generated de novo, such as newly formed glass fibers from a furnace, dip bath or spraying of a carbon nanotube-forming catalyst can be the first step after sufficiently cooling the newly formed fiber material. In some embodiments, cooling of newly formed glass fibers can be accomplished with a cooling jet of water which has the CNS-forming catalyst particles dispersed therein.

In some embodiments, application of a CNS-forming catalyst can be performed in lieu of application of a sizing when generating a fiber and infusing it with CNSs in a continuous process. In other embodiments, the CNS-forming catalyst can be applied to newly formed fiber materials in the presence of other sizing agents. Such simultaneous application of a CNS -forming catalyst and other sizing agents can provide the CNS -forming catalyst in surface contact with the fiber material to ensure CNS infusion. In yet further embodiments, the CNS-forming catalyst can be applied to nascent fibers by spray or dip coating while the fiber material is in a sufficiently softened state, for example, near or below the annealing temperature, such that the CNS-forming catalyst is slightly embedded in the surface of the fiber material. When depositing the CNS-forming catalyst on hot glass fiber materials, for example, care should be given to not exceed the melting point of the CNS-forming catalyst, thereby causing nanoparticle fusion and loss of control of the CNS characteristics (e.g., diameter) as a result.

Catalyst solutions used for applying the CNS-forming catalyst to the fiber material can be in any common solvent that allows the CNS-forming catalyst to be uniformly dispersed throughout. Such solvents can include, without limitation, water, acetone, hexane, isopropyl alcohol, toluene, ethanol, methanol, tetrahydrofuran (THF), cyclohexane or any other solvent with controlled polarity to create an appropriate dispersion of the CNS-forming catalytic nanoparticles therein. Concentrations of CNS-forming catalyst in the catalyst solution can be in a range from about 1:1 to about 1:10,000 catalyst to solvent.

In some embodiments, after applying the CNS-forming catalyst to the fiber material, the fiber material can be optionally heated to a softening temperature. This step can aid in embedding the CNS-forming catalyst in the surface of the fiber material to encourage seeded growth and prevent tip growth where the catalyst floats at the tip of the leading edge a growing CNS. In some embodiments heating of the fiber material after disposing the CNS-forming catalyst on the fiber material can be at a temperature between about 500° C. and about 1000° C. Heating to such temperatures, which can also be used for CNS growth, can serve to remove any pre-existing sizing agents on the fiber material allowing deposition of the CNS-forming catalyst directly on the fiber material. In some embodiments, the CNS-forming catalyst can also be placed on the surface of a sizing coating prior to heating. The heating step can be used to remove sizing material while leaving the CNS-forming catalyst disposed on the surface of the fiber material. Heating at these temperatures can be performed prior to or substantially simultaneously with the introduction of a carbon-containing feedstock gas for CNS growth.

In some embodiments, the process of infusing CNSs to a fiber material includes removing sizing agents from the fiber material, applying a CNS-forming catalyst to the fiber material after sizing removal, heating the fiber material to at least about 500° C., and synthesizing CNSs on the fiber material. In some embodiments, operations of the CNS infusion process include removing sizing from a fiber material, applying a CNS-forming catalyst to the fiber material, heating the fiber material to a temperature operable for CNS synthesis and spraying a carbon plasma onto the catalyst-laden fiber material. Thus, where commercial fiber materials are employed, processes for constructing CNS-infused fibers can include a discrete step of removing sizing from the fiber material before disposing the catalytic nanoparticles on the fiber material. Some commercial sizing materials, if present, can prevent surface contact of the CNS-forming catalyst with the fiber material and inhibit CNS infusion to the fiber material. In some embodiments, where sizing removal is assured under CNS growth conditions, sizing removal can be performed after deposition of the CNS forming catalyst but just prior to or during providing a carbon-containing feedstock gas.

The CNS-infused fiber material includes a fiber material of spoolable dimensions, a barrier coating conformally disposed about the fiber material, and CNSs infused to the fiber material. The infusion of CNSs to the fiber material can include a bonding motif of direct bonding of individual CNSs to the fiber material or indirect bonding via a transition metal NP, barrier coating, or both.

Without being bound by theory, transition metal NPs, which serve as a CNS-forming catalyst, can catalyze CNS growth by forming a CNS growth seed structure. In one aspect, the CNS-forming catalyst can remain at the base of the carbon fiber material, locked by the barrier coating, and infused to the surface of the carbon fiber material. In such a case, the seed structure initially formed by the transition metal nanoparticle catalyst is sufficient for continued non-catalyzed seeded CNS growth without allowing the catalyst to move along the leading edge of CNS growth, as often observed in the art. In such a case, the CNS-forming catalyst (e.g., nanoparticle) serves as a point of attachment for the CNS to the fiber material. The presence of the barrier coating can also lead to further indirect bonding motifs.

For example, the CNS-forming catalyst can be locked into the barrier coating, as described above, but not in surface contact with fiber material. In such a case a stacked structure with the barrier coating disposed between the CNS-forming catalyst and fiber material results. In either case, the CNSs formed can be infused to the fiber material, especially carbon fiber material. In some aspects, some barrier coatings will still allow the CNS growth catalyst to follow the leading edge of the growing nanotube. In such cases, this can result in direct bonding of the CNSs to the fiber material or, optionally, to the barrier coating. Regardless of the nature of the actual bonding motif formed between the carbon nanotubes and the fiber material, the infused CNS is robust and allows the CNS-infused fiber material to exhibit carbon nanotube properties and/or characteristics.

Again, without being bound by theory, when growing CNSs on fiber materials, the elevated temperatures and/or any residual oxygen and/or moisture that can be present in the reaction chamber can damage the fiber material, especially carbon fiber material. Moreover, the fiber material itself can be damaged by reaction with the CNS-forming catalyst itself. By way of nonlimiting example, a carbon fiber material can behave as a carbon feedstock to the catalyst at the reaction temperatures employed for CNS synthesis. Such excess carbon can disturb the controlled introduction of the carbon feedstock gas and can even serve to poison the catalyst by overloading it with carbon.

The barrier coating employed in one aspect of the disclosure may be designed to facilitate CNS synthesis on fiber materials. Without being bound by theory, the coating can provide a thermal barrier to heat degradation and/or can be a physical barrier preventing exposure of the fiber material to the environment at the elevated temperatures. Alternatively or additionally, it can minimize the surface area contact between the CNS-forming catalyst and the fiber material and/or it can mitigate the exposure of the fiber material to the CNS-forming catalyst at CNS growth temperatures.

Barrier coatings can include, for example, an alkoxysilane, methylsiloxane, an alumoxane, alumina nanoparticles, spin on glass and glass nanoparticles. As described below, the CNS-forming catalyst can be added to the uncured barrier coating material and then applied to the fiber material together. In other aspects the barrier coating material can be added to the fiber material prior to deposition of the CNS-forming catalyst. The barrier coating material can be of a thickness sufficiently thin to allow exposure of the CNS-forming catalyst to the feedstock for subsequent CVD growth. In some aspects, the thickness is less than or about equal to the effective diameter of the CNS-forming catalyst. In some aspects, the thickness of the barrier coating is in a range from between about 10 nm to about 100 nm. The barrier coating can also be less than 10 nm, including 1 nm, 2 nm, 3 nm, 4 nm, 5 nm, 6 nm, 7 nm, 8 nm, 9 nm, 10 nm, and any value in between.

Without being bound by theory, the barrier coating can serve as an intermediate layer between the fiber material and the CNSs and serves to mechanically infuse the CNSs to the fiber material. Such mechanical infusion still provides a robust system in which the fiber material serves as a platform for organizing the CNSs while still imparting properties of the CNSs to the fiber material. Moreover, the benefit of including a barrier coating is the immediate protection it provides the fiber material, especially carbon fiber material, from chemical damage due to exposure to moisture and/or any thermal damage due to heating of the fiber material at the temperatures used to promote CNS growth.

In some embodiments, the fiber material can be optionally treated with a plasma to prepare the fiber surface to accept the catalyst. For example, a plasma treated glass fiber material can provide a roughened glass fiber surface in which the carbon nanotube-forming catalyst can be deposited. In some embodiments, the plasma also serves to “clean” the fiber surface. The plasma process for “roughing” the fiber surface thus facilitates catalyst deposition. The roughness is typically on the scale of nanometers. In the plasma treatment process, craters or depressions are formed that are nanometers deep and nanometers in diameter. Such surface modification can be achieved using a plasma of any one or more of a variety of different gases, including, without limitation, argon, helium, oxygen, ammonia, nitrogen and hydrogen.

In some embodiments, where a fiber material being employed has a sizing material associated with it, such sizing can be optionally removed prior to catalyst deposition. Optionally, the sizing material can be removed after catalyst deposition. In some embodiments, sizing material removal can be accomplished during CNS synthesis or just prior to CNS synthesis in a pre-heat step. In other embodiments, some sizing materials can remain throughout the entire CNS synthesis process.

The infused CNSs disclosed herein can effectively function as a replacement for conventional fiber material “sizing.” The infused CNSs are more robust than conventional sizing materials and can improve the fiber-to-matrix interface in composite materials and, more generally, improve fiber-to-fiber interfaces. Indeed, the CNS-infused fiber materials disclosed herein are themselves composite materials in the sense the CNS-infused fiber material properties will be a combination of those of the fiber material as well as those of the infused CNSs. Consequently, some aspects of the present disclosure may provide a means to impart desired properties to a fiber material that otherwise lack such properties or possesses them in insufficient measure. Fiber materials can be tailored or engineered to meet the requirements of specific applications. The CNSs acting as sizing can protect fiber materials from absorbing moisture due to the hydrophobic CNS structure. Moreover, hydrophobic matrix materials, as further exemplified below, interact well with hydrophobic CNSs to provide improved fiber to matrix interactions.

Despite the beneficial properties imparted to a fiber material having infused CNSs described above, the compositions of the present disclosure may include further “conventional” sizing agents. Such sizing agents vary widely in type and function and include, for example, surfactants, anti-static agents, lubricants, siloxanes, alkoxysilanes, aminosilanes, silanes, silanols, polyvinyl alcohol, starch, and mixtures thereof. Such secondary sizing agents can be used to protect the CNSs themselves or provide further properties to the fiber not imparted by the presence of the infused CNSs.

Compositions of some aspects of the disclosure can further include a matrix material to form a composite with the CNS-infused fiber material, which may be arranged according to a composite matrix core. Such matrix materials can include, for example, an epoxy, a polyester, a vinylester, a polyetherimide, a polyetherketoneketone, a polyphthalamide, a polyetherketone, a polytheretherketone, a polyimide, a phenol-formaldehyde, and a bismaleimide. Matrix materials useful in the present disclosure may include any of the known matrix materials (see Mel M. Schwartz, Composite Materials Handbook (2nd ed. 1992)). Matrix materials more generally can include resins (polymers), both thermosetting and thermoplastic, metals, ceramics, and cements.

Thermosetting resins useful as matrix materials include phthalic/maelic type polyesters, vinyl esters, epoxies, phenolics, cyanates, bismaleimides, and nadic end-capped polyimides (e.g., PMR-15). Thermoplastic resins include polysulfones, polyamides, polycarbonates, polyphenylene oxides, polysulfides, polyether ether ketones, polyether sulfones, polyamide-imides, polyetherimides, polyimides, polyarylates, and liquid crystalline polyester.

Metals useful as matrix materials include alloys of aluminum such as aluminum 6061, 2024, and 713 aluminum braze. Ceramics useful as matrix materials include carbon ceramics, such as lithium aluminosilicate, oxides such as alumina and mullite, nitrides such as silicon nitride, and carbides such as silicon carbide. Cements useful as matrix materials include carbide-base cermets (tungsten carbide, chromium carbide, and titanium carbide), refractory cements (tungsten-thoria and barium-carbonate-nickel), chromium-alumina, nickel-magnesia iron-zirconium carbide. Any of the above-described matrix materials can be used alone or in combination.

In a variation of the illustrative embodiments, the continuous processing line for CNS growth is used to provide an improved filament winding process. In this variation, CNSs are formed on substrates (e.g., graphite tow, glass roving, etc.) using apparatus 100 in a system that allows for the substrate to pass through apparatus 100 in a continuous manner then passed through a resin bath to produce resin-impregnated, CNS-infused substrate. After resin impregnation, the substrate can be positioned on the surface of a rotating winder by a delivery head. The substrate then winds onto the winder in a precise geometric pattern in known fashion. These additional sub operations can be performed in continuous fashion, extending the basic continuous process.

The filament winding process described above provides pipes, tubes, or other forms as are characteristically produced via a male mold. But the forms made from the filament winding process disclosed herein differ from those produced via conventional filament winding processes. Specifically, in the process disclosed herein, the forms are made from composite materials that include CNS-infused substrates. Such forms will therefore benefit from enhanced strength, etc., as provided by the CNS-infused substrates.

In the continuous processes described herein, the residence time of the fiber material in CNS growth zones 108 and intermediate zone 104 can be modulated to control CNS growth, including, but not limited to CNT length. Residence time of the fiber in apparatus 100 can range from about 1 second to about 300 seconds, or about 100 second to about 10 seconds. As describe above, this provides a means to control specific properties of the CNSs grown through modulation of the carbon feedstock and carrier gas flow rates and reaction temperature. Additional control of the CNS properties can be obtained by controlling, for example, the size of the catalyst used to prepare the CNSs. For example, 1 nm transition metal nanoparticle catalysts can be used to provide SWNTs in particular. Larger catalysts can be used to prepare predominantly MWNTs.

In the continuous processes described herein, the feed gas residence time in CNS growth zones 108 and intermediate zone 104 can be modulated to control CNS growth, including, but not limited to CNT length. Residence time of feed gas 128 can range from about 0.01 seconds to about 10 seconds, or about 0.5 seconds to about 5 seconds.

In the continuous processes described herein, the percent of feedstock gas in feed gas 128 can be modulated to control CNS growth, including, but not limited to CNT length. The composition of feed gas 128 can include feedstock gas in an amount ranging from about 0.01% to about 50%, or about 10% to about 40%.

Additionally, the CNS growth processes employed are useful for providing a CNS-infused fiber material with uniformly distributed CNSs on fiber materials while avoiding bundling and/or aggregation of the CNSs that can occur in processes in which pre-formed CNSs are suspended or dispersed in a solvent solution and applied by hand to the fiber material. Such aggregated CNSs tend to adhere weakly to a fiber material and the characteristic CNS properties are weakly expressed, if at all.

CNS-infused fiber materials can be used in a myriad of applications, only some of which are disclosed herein. For example, CNS-infused conductive fibers can be used in the manufacture of electrodes for superconductors. In the production of superconducting fibers, it can be challenging to achieve adequate adhesion of the superconducting layer to a fiber material due, in part, to the different coefficients of thermal expansion of the fiber material and of the superconducting layer. Another difficulty in the art arises during the coating of the fibers by the CVD process. For example, reactive gases, such as hydrogen gas or ammonia, can attack the fiber surface and/or form undesired hydrocarbon compounds on the fiber surface and make good adhesion of the superconducting layer more difficult. CNS-infused fiber materials with barrier coating can overcome these aforementioned challenges in the art.

Additional CNT-Infused Fiber Embodiments: In some embodiments, CVD-promoted carbon nanotube growth on the catalyst-laden fiber material can be performed with apparatus 100. Such CNT-infused fiber materials are described in commonly owned U.S. patent applications Ser. Nos. 12/611,073, 12/611,101, and 12/611,103, all filed on Nov. 2, 2009, and Ser. No. 12/938,328, filed on Nov. 2, 2010, each of which is incorporated herein by reference in its entirety. Illustrative fiber types that can be infused with CNTs include, for example, carbon fibers, glass fibers, metal fibers, ceramic fibers, and organic (e g., aramid) fibers, any of which can be used in the present embodiments. As described in these co-pending patent applications, a fiber material is modified to provide a layer (typically no more than a monolayer) of catalytic nanoparticles on the fiber material for the purpose of growing CNTs thereon. Such CNT-infused fibers can be readily prepared in spoolable lengths from commercially available continuous fibers or continuous fiber forms (e.g., fiber tows or fiber tapes). Shortening of the continuous fibers into chopped fibers can take place following CNT infusion thereon, if desired. Additional disclosure regarding CNT-infused fiber materials is presented hereinafter.

To infuse CNTs to a fiber material, the CNTs are synthesized directly on the fiber material. In some embodiments, this is accomplished by first disposing a CNT-forming catalyst (e.g., catalytic nanoparticles) on the fiber material. A number of preparatory processes can be performed prior to this catalyst deposition.

The CNT-forming catalyst can be prepared as a liquid solution that contains the CNT-forming catalyst as transition metal catalytic nanoparticles. The diameters of the synthesized CNTs are related to the size of the transition metal catalytic nanoparticles as described above.

In the CNT growth process, CNTs grow at the sites of transition metal catalytic nanoparticles that are operable for CNT growth. The presence of a strong plasma-creating electric field can be optionally employed to affect CNT growth. That is, the growth tends to follow the direction of the electric field. By properly adjusting the geometry of the plasma spray and electric field, vertically aligned CNTs (i.e., perpendicular to the longitudinal axis of the fiber material) can be synthesized. Under certain conditions, even in the absence of a plasma, closely-spaced CNTs can maintain a substantially vertical growth direction resulting in a dense array of CNTs resembling a carpet or forest.

In some embodiments, CNT-infused fiber materials containing substantially parallel-aligned CNTs can be produced. CNT-infused fibers containing substantially parallel-aligned CNTs are described in commonly owned U.S. patent application Ser. No. 13/019,248, filed Feb. 1, 2011, which is incorporated herein by reference in its entirety. In some embodiments, a CNT-infused fiber material that contains a fiber material and CNTs infused to the fiber material that are aligned substantially perpendicular to the surface of the fiber material can be reoriented so as to form a layer of infused CNTs that are aligned substantially parallel to the longitudinal axis of the fiber material.

In forming CNTs, growth tends to follow the direction of the applied electric field or magnetic field. By properly adjusting the geometry of the plasma spray or like carbon feedstock source and the electric field or magnetic field in a CNT growth process that produces substantially parallel-aligned CNTs, a separate realignment step after CNT synthesis can be avoided.

In some aspects, the maximum distribution density, expressed as percent coverage, that is, the surface area of fiber covered, can be as high as about 55% assuming about 8 nm diameter CNTs with 5 walls. This coverage is calculated by considering the space inside the CNTs as being “fillable” space. Various distribution/density values can be achieved by varying catalyst dispersion on the surface as well as controlling gas composition and process speed. Typically for a given set of parameters, a percent coverage within about 10% can be achieved across a fiber surface. Higher density and shorter CNTs are useful for improving mechanical properties, while longer CNTs with lower density are useful for improving thermal and electrical properties, although increased density is still favorable. A lower density can result when longer CNTs are grown. This can be the result of the higher temperatures and more rapid growth causing lower catalyst particle yields.

According to one aspect of the present disclosure, any amount of the fiber surface area, from 0-55% of the fiber can be covered assuming an 8 nm diameter, 5-walled MWNT (again this calculation counts the space inside the CNTs as finable). This number is lower for smaller diameter CNTs and more for greater diameter CNTs. 55% surface area coverage is equivalent to about 15,000 CNTs/micron². Further CNT properties can be imparted to the fiber material in a manner dependent on CNT length, as described above. Infused CNTs can vary in length ranging from between about 1 micron to about 500 microns, including about 1 micron, 2 microns, 3 microns, 4 micron, 5, microns, 6, microns, 7 microns, 8 microns, 9 microns, 10 microns, 15 microns, 20 microns, 25 microns, 30 microns, 35 microns, 40 microns, 45 microns, 50 microns, 60 microns, 70 microns, 80 microns, 90 microns, 100 microns, 150 microns, 200 microns, 250 microns, 300 microns, 350 microns, 400 microns, 450 microns, 500 microns, and all values in between. CNTs can also be less than about 1 micron in length, including about 0.5 microns, for example. CNTs can also be greater than 500 microns, including for example, about 510 microns, 520 microns, 550 microns, 600 microns, 700 microns, and all values in between.

CNTs lend their characteristic properties such as mechanical strength, low to moderate electrical resistivity, high thermal conductivity, and the like to the CNT-infused fiber material. For example, in some aspects, the electrical resistivity of a CNT-infused fiber material is lower than the electrical resistivity of a parent fiber material. More generally, the extent to which the resulting CNT-infused fiber expresses these characteristics can be a function of the extent and density of coverage of the fiber material by the CNTs, as well as an orientation of the CNTs relative to an axis of the fiber material.

In some aspects, compositions that include spoolable lengths of CNT-infused fiber materials can have various uniform regions with different lengths of CNTs. For example, it can be desirable to have a first portion of CNT-infused fiber material with uniformly shorter CNT lengths to enhance shear strength properties, and a second portion of the same spoolable material with a uniform longer CNT length to enhance electrical or thermal properties for use in power transmission cables according to one aspect of the present disclosure.

It is understood that modifications which do not substantially affect the activity of the various embodiments of this invention are also included within the definition of the invention provided herein. Accordingly, the following Examples are intended to illustrate but not limit the present invention.

In some examples below, a dynamic snapshot of a substrate in the process of passing through the apparatus was taken. A dynamic snapshot is used to investigate the growth profile of CNS on the substrate. Generally, after the apparatus reached equilibrium for a given set of parameters, e.g., linespeed, temperature, and feed gas flow rate, the substrate was cut near both ends and rapidly removed from apparatus. Data was collected at various points on the substrate to characterize the CNS material and/or the substrate itself. The dynamic snapshot can be used to investigate the stability of apparatus. In some embodiments, the parameters and/or configuration of apparatus can be adjusted, including for optimization, based on a dynamic snapshot(s).

Example 1 provides dynamic snapshot of a glass fiber passed through an 80 inch long apparatus configured with a first end zone, first CNS growth zone, intermediate zone, second CNS growth zone, and second end zone in series. The first and second CNS growth zones were maintained at 750° C. while the intermediate zone was maintained at 475° C. The nitrogen at 1 lpm and acetylene at 0.4 lpm were consistent between the growth zones and intermediate zones. Dynamic snapshots were taken at two different linespeeds (15 cm/min and 1.26 m/min). FIG. 5 provides the weight percent of CNTs relative to the fiber at various points along the length of the apparatus. The 15 cm/min linespeed produced a higher weight percent of carbon nanotubes, which is expected since it has a longer residence time in the various zones than does the 1.26 m/min linespeed. The intermediate zone, while flowing feed gas, is at a low enough temperature to not facilitate growth of CNTs. In this example it is believed that, the longer residence time of a catalyst in the intermediate zone terminates catalytic activity, i.e., renders the catalyst no longer available for CNS production, as illustrated with linespeed 15 cm/min where the weight percent carbon does not significantly increase from entering the intermediate zone to exiting the second CNS growth zone. In contrast, a linespeed of 1.26 m/min provides a short enough residence so that growth can continue in the second CNS growth zone, in this case almost double the CNT on the fiber.

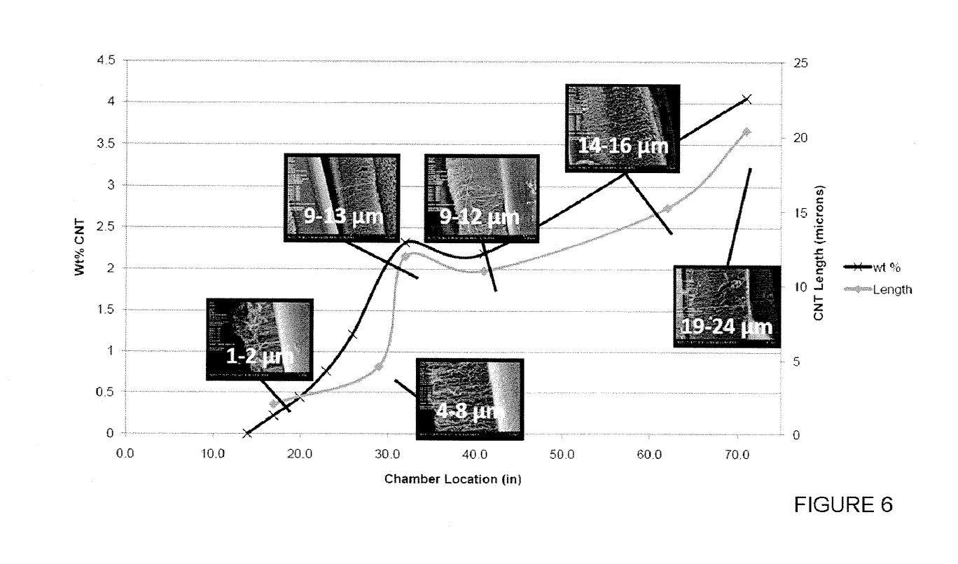

Example 2 provides a dynamic snapshot of a fiber passing through an apparatus and conditions of Example 1 with a linespeed of 1.26 m/min. The dynamic snapshot, FIG. 6, provided demonstrates not only weight percent of produced CNTs but also a length analysis. Based on the result, it is believed that the growth in the second CNS growth zone was primarily due to extending the length of the CNTs as opposed to nucleating new CNTs.

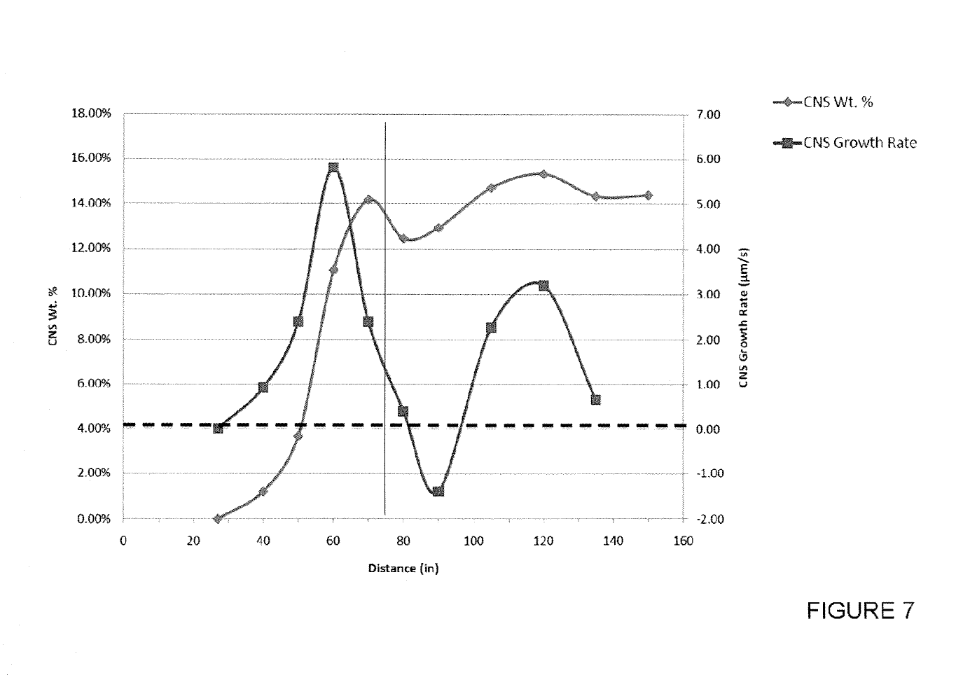

Example 3 provides a dynamic snapshot of a fiber (Owens Coring Advantex Fiber (a glass fiber) with 735 tex) passing through a 160 inch apparatus with a end zone on either end at lower temperatures to assist in rapidly cooling the sample, two growth zones maintained at various temperatures between 650° C. and 800° C., and an intermediate zone maintained at 510° C. with a linespeed of 10 fpm. The center of the intermediate zone is denoted on FIG. 7 with a vertical solid line at approximately 74 inches. The feed gas consisted of acetylene at 0.579 lpm and nitrogen at 1.55 lpm yielding a feed gas of approximately 27% acetylene. Provided in FIG. 7 is the weight percent of CNS relative to the fiber and the CNS growth rate, which is the first derivative of the weight percent. In this example, the growth rate in the intermediate zone dropped to zero. After the fiber passes through the intermediate zone, the growth rate returned to a positive value. This demonstrates that with high line speeds that feed gas can be introduced at temperatures below CNS growth conditions, which is also below sooting conditions, and growth will continue after said intermediate zone. This can allow for less sooting at the feed gas inlet which translates to a cleaner apparatus for long-term experiments.

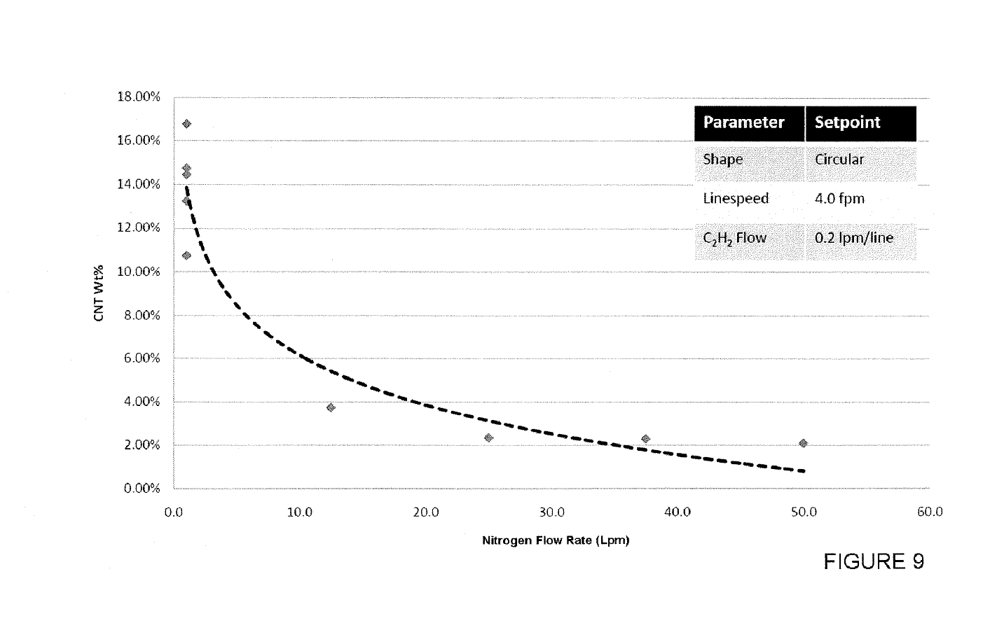

Example 4 investigated the effect of nitrogen flow rate on growth of CNSs on fibers. Using an apparatus with a circular enclosure, a linespeed of 1.26 m/min, and a constant acetylene flow of 0.2 lpm, the flow rate of nitrogen was adjusted. By increasing the flow rate of nitrogen, the catalyst was exposed to less acetylene. The weight percent of CNS to fiber was measured on the final product. It is believed that FIG. 9 demonstrates that lower nitrogen flow rates, i.e., less dilution of acetylene, yield more CNS product. Further, increasing the time the substrate is exposed to the feed gas before leaving the system increases the efficiency of converting feed gas carbon to CNS carbon.

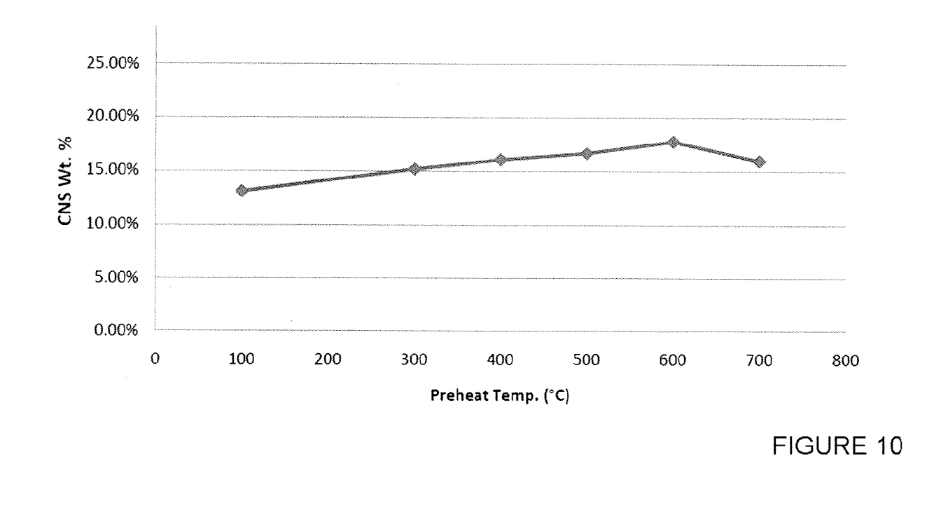

Example 5 investigated the effect of preheating the feed gas on CNS production. A series of experiments were run with preheating acetylene before introduction into the CNS growth zone. The CNS weight percent for various acetylene and nitrogen flow rates were analyzed for the resultant fibers, FIG. 10. It is believed that the results demonstrate that preheating the feed gas increases CNS production provided preheating does not exceed the decomposition temperature of feed gas, i.e., above 600° C. for acetylene as shown in this example.

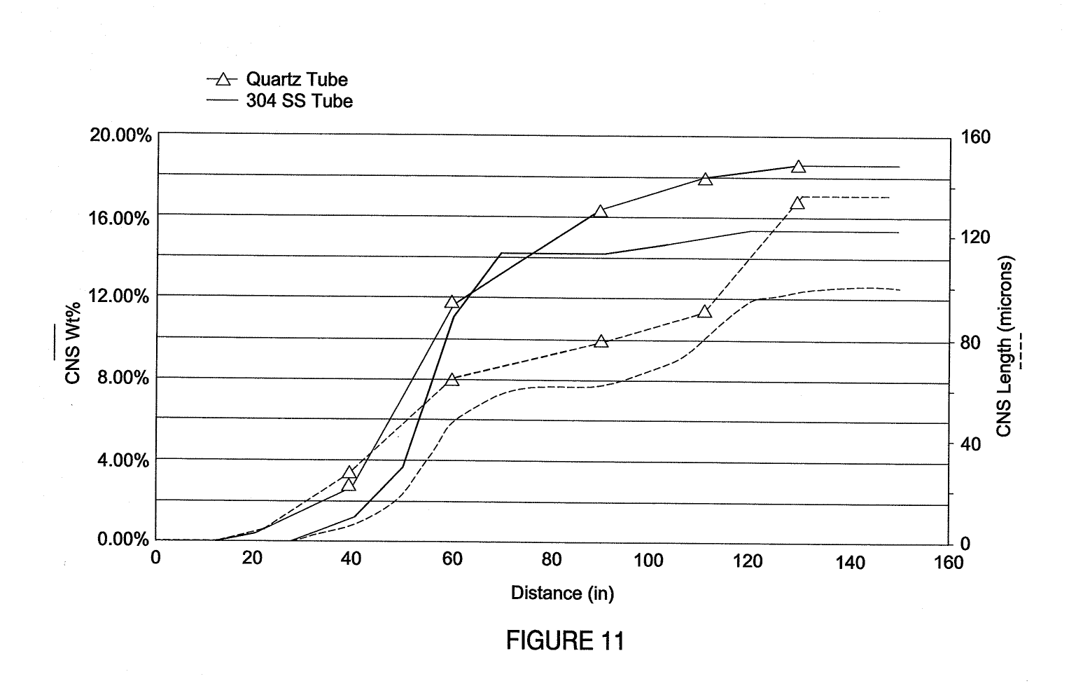

Example 6 investigated the effect of CNS growth zone enclosure material. Under the same experimental conditions, a CNS-infused fiber was produced with a quartz CNS growth zone enclosure and a second CNS-infused fiber with a 304 stainless steel CNS growth zone enclosure. FIG. 11 provides a dynamic snapshot of the two samples showing quartz provides better CNS growth throughout the apparatus and especially at the end of the chamber. Further, it was observed that running with the quartz enclosures produced less soot.

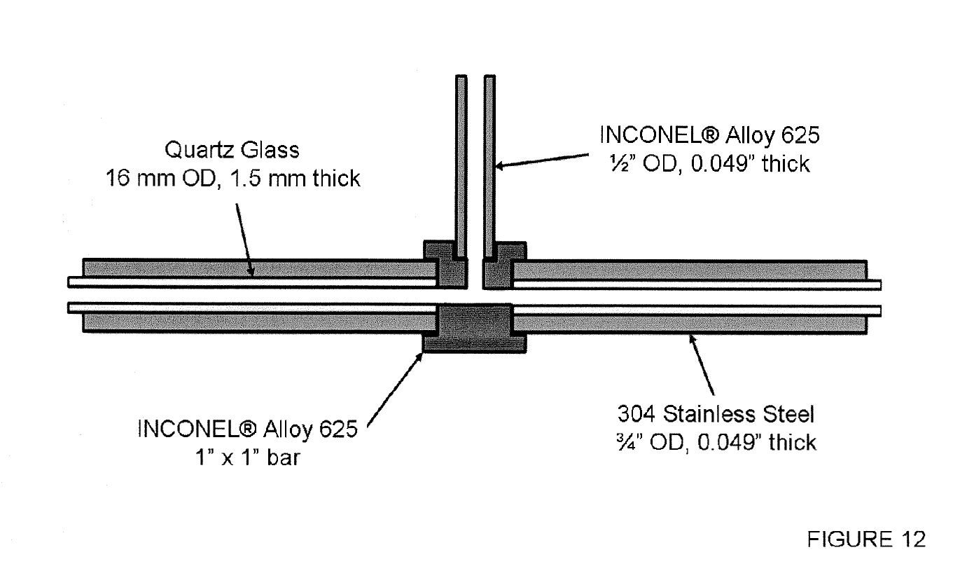

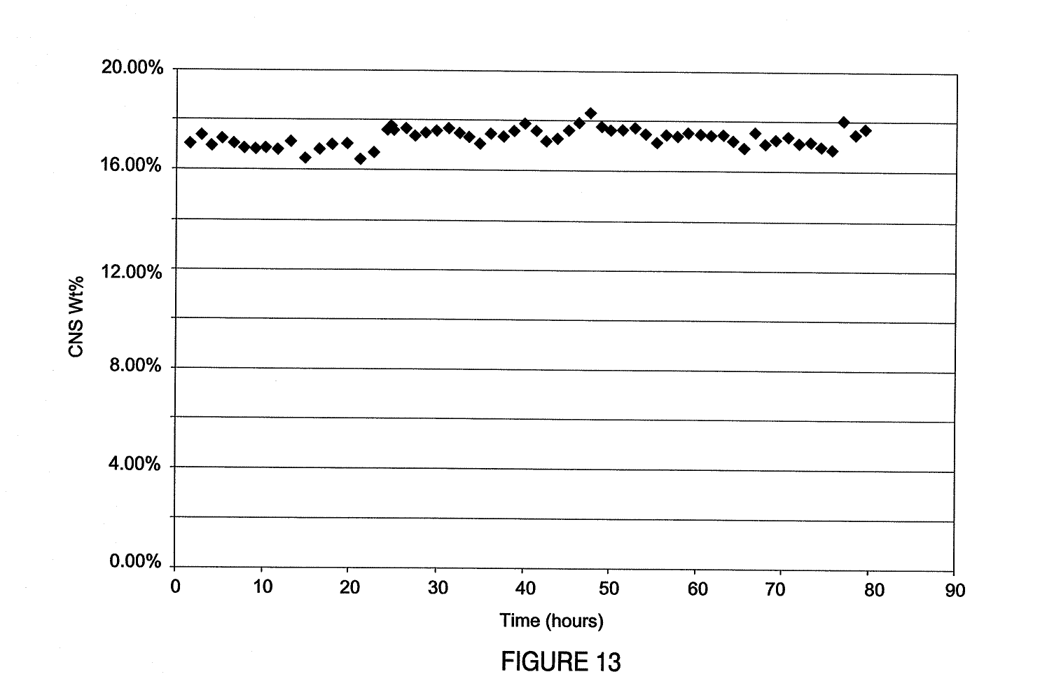

Example 7 investigated long-term running of an apparatus, illustrated in FIG. 12, having CNS growth zone with a concentric enclosure configuration for of stainless steel with a quartz enclosure disposed therein and an intermediate zone being an INCONEL® enclosure with a feed gas inlet of INCONEL® connected thereto. A spoolable substrate was run through the apparatus for 85 hours continuously. FIG. 13 illustrates that CNS growth over the long-term run was consistent. Further, it was observed that less soot was produced and accumulated at the end of the 85-hour run.

It is to be understood that the above-described embodiments are merely illustrative of the present invention and that many variations of the above-described embodiments can be devised by those skilled in the art without departing from the scope of the invention. For example, in this Specification, numerous specific details are provided in order to provide a thorough description and understanding of the illustrative embodiments of the present invention. Those skilled in the art will recognize, however, that the invention can be practiced without one or more of those details, or with other processes, materials, components, etc.

Furthermore, in some instances, well-known structures, materials, or operations are not shown or described in detail to avoid obscuring aspects of the illustrative embodiments. It is understood that the various embodiments shown in the Figures are illustrative, and are not necessarily drawn to scale. Reference throughout the specification to “one embodiment” or “an embodiment” or “some embodiments” means that a particular feature, structure, material, or characteristic described in connection with the embodiment(s) is included in at least one embodiment of the present invention, but not necessarily all embodiments. Consequently, the appearances of the phrase “in one embodiment,” “in an embodiment,” or “in some embodiments” in various places throughout the Specification are not necessarily all referring to the same embodiment. Furthermore, the particular features, structures, materials, or characteristics can be combined in any suitable manner in one or more embodiments. It is therefore intended that such variations be included within the scope of the following claims and their equivalents.

What is claimed is the following:

1. An apparatus for growing carbon nanostructures (CNSs) comprising:
at least two CNS growth zones with at least one intermediate zone disposed therebetween; and
a substrate inlet before the CNS growth zones sized to allow a spoolable length substrate to pass therethrough.

2. The apparatus of claim 1 further comprising:
at least one heater in thermal communication with the at least two CNS growth zones; and
at least one feed gas inlet in fluid communication with the at least two CNS growth zones.

3. The apparatus of claim 1 further comprising:
a CNS nucleation zone disposed between the substrate inlet and a first CNS growth zone.

4. The apparatus of claim 1, wherein the apparatus comprises a plurality of CNS growth zones and a plurality of intermediate zones such that the CNS growth zones and the intermediate zones alternate.

5. The apparatus of claim 1, wherein the at least two CNS growth zones and the at least one intermediate zone are in series.

6. The apparatus of claim 1 comprising one intermediate zone and at least three CNS growth zones.

7. The apparatus of claim 1 further comprising:
at least one end zone in fluid communication with a carrier gas inlet.

8. The apparatus of claim 1, wherein a feed gas inlet is operably connected to at least one intermediate zone.

9. The apparatus of claim 1, wherein a cross-sectional area of the at least two CNS growth zones is no greater than about 600 times a cross-sectional area of the spoolable length substrate.

10. The apparatus of claim 1, wherein the at least one CNS growth zones have an internal volume no greater than about 10,000 times a volume of a section of the spoolable length substrate having a length substantially equal to the length of a corresponding CNS growth zone.

11. The apparatus of claim 1, wherein the at least two CNS growth zones are formed by an enclosure comprising a material selected from the group consisting of a metal, a metal alloy, a refractory glass, quartz, a ceramic, a composite, and any combination thereof.

12. The apparatus of claim 1 further comprising:
at least one sensor operably connected to the apparatus.

13. The apparatus of claim 1, wherein at least one CNS growth zone or at least one intermediate zone further comprises a magnetic field, an electric field, a hot filament, or any combination thereof.

14. The apparatus of claim 1, wherein at least one intermediate zone is configured to operate at a lower temperature than the at least two CNS growth zones.

15. The apparatus of claim 1, wherein the at least one intermediate zone comprise at least one feed gas inlet.

16. An apparatus for growing carbon nanostructures (CNSs) comprising:
at least two CNS growth zones, wherein each CNS growth zone has a cross-sectional area less than about 10,000 times greater than a substrate cross-sectional area to be passed therethrough;
at least one intermediate zone disposed between the at least two CNS growth zones; and
a substrate inlet before the CNS growth zones sized to allow a spoolable length substrate to pass therethrough.

17. The apparatus of claim 16 further comprising:
a CNS nucleation zone disposed between the substrate inlet and a first CNS growth zone.

18. The apparatus of claim 16, wherein the at least two CNS growth zones and the at least one intermediate zone are in series.

19. The apparatus of claim 16 comprising one intermediate zone and at least three CNS growth zones.

20. The apparatus of claim 16 further comprising:
at least one end zone in fluid communication with a carrier gas inlet.

21. The apparatus of claim 16, wherein the at least two CNS growth zones are formed by an enclosure comprising a material selected from the group consisting of a metal, a metal alloy, a refractory glass, quartz, a ceramic, a composite, and any combination thereof.

22. The apparatus of claim 16, wherein at least one CNS growth zone or at least one intermediate zone comprises a magnetic field, an electric field, a hot filament, or any combination thereof.

23. The apparatus of claim 16, wherein at least one intermediate zone is configured to operate at a lower temperature than the at least two CNS growth zones.

24. The apparatus of claim 16, wherein at least one intermediate zone comprises at least one feed gas inlet.

25. A system for growing carbon nanostructures (CNSs), the system comprising:
at least one apparatus that comprises at least two CNS growth zones along a substrate path with at least one intermediate zone disposed therebetween;
at least one winder operably capable of transporting a spoolable length substrate along the substrate path; and
at least one motor operably connected to the winder.

26. The system of claim 25 further comprising:
an enclosure that comprises at least a portion of the apparatus.

27. The system of claim 25 further comprising:
an additional component disposed along the substrate path selected from the group consisting of a substrate splitter, a substrate manipulator, a deposition component, a removal component, a impregnation component, and any combination thereof.

28. The system of claim 25 further comprising:
an additional component operable connected to the system selected from the group consisting of a thermal sensor; a gas sensors; a gas analyzer; a camera; a microscope; and any combination thereof.

29. The system of claim 25, wherein a cross-sectional area of the at least two CNS growth zones are no greater than about 10,000 times a cross-sectional area of the spoolable length substrate.

30. The system of claim 25, wherein the at least one CNS growth zones have an internal volume no greater than about 10,000 times a volume of a section of the spoolable length substrate having a length substantially equal to the length of a corresponding CNS growth zone.

31. The system of claim 25, wherein at least one intermediate zone is configured to operate at a lower temperature than the at least two CNS growth zones.

32. The system of claim 25, wherein at least one intermediate zone comprises at least one feed gas inlet.

33. The system of claim 25 comprising at least two apparatuses along the substrate path.

34. An method for growing carbon nanostructures (CNSs), the method comprising:
transporting at least a portion of a spoolable length substrate along a substrate path that comprises at least two CNS growth zones and at least one intermediate zone disposed therebetween;
heating at least the CNS growth zones; and
passing a feed gas through at least the CNS growth zones.

35. The method of claim 34, wherein at least one intermediate zone is at a lower temperature than the at least two CNS growth zones.

36. The method of claim 34, wherein at least one intermediate zone comprises at least one feed gas inlet.

37. The method of claim 34, wherein at least one CNS growth zone or at least one intermediate zone further comprises a magnetic field, an electric field, a hot filament, and any combination thereof.

38. The method of claim 34, wherein transporting at least a portion of the spoolable length substrate along the substrate path takes place at a linespeed of about 1.5 to about 50 m/min.

39. The method of claim 34, wherein at least a portion of the spoolable length substrate comprises a catalyst prior to passing through the at least two CNS growth zones.

40. The method of claim 34 further comprising:
growing a plurality of CNSs on at least a portion of the substrate.

41. The method of claim 34 further comprising:
heating the feed gas prior to passing the feed gas through at least one CNS growth zone.

42. The method of claim 34 further comprising:
transporting at least a portion of at least one additional spoolable length substrate along at least one additional substrate path that comprises at least two CNS growth zones and at least one intermediate zone disposed therebetween.
